(19) United States
(12) Patent Application Publication
(10) Pub. No.: US 2026/0033004 A1
(43) Pub. Date: Jan. 29, 2026

(54) ARRAY SUBSTRATE AND DISPLAY DEVICE

(71) Applicants: HEFEI BOE DISPLAY TECHNOLOGY CO., LTD., Hefei, Anhui (CN); BOE TECHNOLOGY GROUP CO., LTD., Beijing (CN)

(72) Inventors: Maoxiu ZHOU, Beijing (CN); Haipeng YANG, Beijing (CN); Ke DAI, Beijing (CN); Min CHENG, Beijing (CN); Chunxu ZHANG, Beijing (CN); Xiaoting JIANG, Beijing (CN); Yue YANG, Beijing (CN)

(21) Appl. No.: 18/994,016

(22) PCT Filed: Apr. 26, 2024
(86) PCT No.: PCT/CN2024/089967

§ 371 Date: Jan. 13, 2025

(30) Foreign Application Priority Data
May 26, 2023 (CN) 202310610233.2

(51) Int. Cl. H10D 86/40; G09G 3/20; H10D 86/60

(52) U.S. Cl. CPC H10D 86/443; G09G 3/2092; H10D 86/60; G09G 2300/0426; G09G 2330/06

(57) ABSTRACT

An array substrate and a display device are provided. An array substrate includes a base substrate, a first data line, a virtual signal line and a driver module, wherein the first data line, the virtual signal line and the driver module are arranged on the base substrate, the driver module includes a multi-stage driving circuit; the multi-stage driving circuit is arranged along the first direction; the driving circuit is used to provide a driving signal; the first data line is arranged between at least two adjacent driving circuits, and the first data line is used to provide a data voltage; the virtual signal line is further arranged between at least two adjacent driving circuits; the virtual signal line is in a floating state. In the embodiments of the present disclosure, the virtual signal line is provided to ensure etching uniformity.

### CROSS-REFERENCE TO RELATED APPLICATIONS

The present application is the U.S. national phase of PCT Application No. PCT/CN2024/089967 filed on Apr. 26, 2024, which claims a priority to the Chinese patent application No. 202310610233.2 filed in China on May 26, 2023, the entire contents each of which are incorporated herein by reference for all purposes.

### TECHNICAL FIELD

The present disclosure relates to the field of display technology, and in particular, to an array substrate and a display device.

### BACKGROUND

The improvement in display panel quality is an ongoing topic, and ultra-narrow bezel display panels are increasingly being used. In related art, in order to achieve a narrow bezel, a driver module comprising multiple stages of driving circuits can be arranged at an upper side or a lower side of an array substrate.

### SUMMARY

In the first aspect, an embodiment of the present disclosure provides an array substrate, including a base substrate, a first data line, a virtual signal line and a driver module, wherein the first data line, the virtual signal line and the driver module are arranged on the base substrate, wherein the first data line, the virtual signal line and the driver module are arranged in a peripheral region of the array substrate, the peripheral region at least partially surrounds a display region, the display region includes a first gate line extending along a first direction and a second data line extending along a second direction, the first data line is electrically connected to the second data line, and the first direction intersects the second direction;

the driver module is arranged at a first side of the array substrate; the first side is a side arranged in an extension direction of the second data line;

the driver module includes multiple stages of driving circuits; the multiple stages of driving circuits are arranged along the first direction; the driving circuit is configured to provide a driving signal;

the first data line is arranged between at least two adjacent driving circuits, and the first data line is configured to provide a data voltage;

the virtual signal line is further arranged between the at least two adjacent driving circuits; the virtual signal line is in a floating state.

Optionally, the first data line and the virtual signal line are formed in a same conductive layer.

Optionally, at least one of the virtual signal lines is arranged between two adjacent first data lines;

the virtual signal line extends along the second direction.

Optionally, the peripheral region includes a driving circuit region and a side region; the driver module is arranged in the driving circuit region;

the side region is arranged at two opposite sides of an arrangement direction of the driving circuit region;

the side region includes a first signal line region and a first electrostatic discharge region; the array substrate further includes a plurality of clock signal lines arranged in the first signal line region, and a first electrostatic discharge circuit arranged in the first electrostatic discharge region;

the first electrostatic discharge circuit is electrically connected to the clock signal line, and configured to provide electrostatic protection for the clock signal line.

Optionally, the array substrate further includes a first one of first low voltage lines, a second low voltage line, a frame reset line, a first control voltage line, a second control voltage line and an initial voltage line that are arranged in the first signal line region;

the first electrostatic discharge circuit is further electrically connected to each of the first one of the first low voltage lines, the second low voltage line, the frame reset line, the first control voltage line, the second control voltage line and the initial voltage line, and is configured to provide electrostatic protection for the first one of the first low voltage lines, the second low voltage line, the frame reset line, the first control voltage line, the second control voltage line and the initial voltage line;

the first one of the first low voltage lines is configured to provide a first low voltage signal, the frame reset line is configured to provide a frame reset signal, the first control voltage line is configured to provide a first control voltage, the second control voltage line is configured to provide a second control voltage, and the initial voltage line is configured to provide an initial voltage.

Optionally, the clock signal line, the second low voltage line, the frame reset line, the first control voltage line and the second control voltage line are arranged at a first side, a second side and a third side of the first electrostatic discharge circuit; the first one of the first low voltage lines is arranged at the first side and the second side of the first electrostatic discharge circuit; the initial voltage line is arranged at a fourth side of the first electrostatic discharge circuit;

the first side and the fourth side are opposite sides, and the second side and the third side are opposite sides.

Optionally, the array substrate includes a driving circuit region and a display region, the driver module is arranged in the driving circuit region; the driving circuit region includes a wiring region;

the array substrate further includes a second one of first low voltage lines arranged between the driving circuit region and the display region, and a cascade line arranged in the wiring region;

the cascade line is a signal line for cascading the multiple stages of driving circuits included in the driver module; the second one of the first low voltage lines is configured to provide a first low voltage signal;

an orthographic projection of the virtual signal line onto the base substrate overlaps at least partially with an orthographic projection of the cascade line onto the base substrate;

the orthographic projection of the virtual signal line onto the base substrate overlaps at least partially with an orthographic projection of the second one of the first low voltage lines onto the base substrate.

Optionally, the peripheral region includes a virtual driving circuit region; the array substrate includes a virtual driver module arranged in the virtual driving circuit region, and the virtual driving circuit region is arranged between the side region and the display region;

the virtual driver module includes a plurality of virtual driving circuits arranged along the first direction;

the virtual driving circuit includes a virtual driving output end and a virtual input end;

the virtual input end of the virtual driving circuit is disconnected from a virtual driving output end of another virtual driving circuit included in the virtual driver module other than the virtual driving circuit.

Optionally, the array substrate further includes a floating signal line arranged between adjacent virtual driving circuits;

the floating signal line is in a floating state.

Optionally, the array substrate includes the peripheral region and the display region, the peripheral region includes a driving circuit region; the driver module is arranged in the driving circuit region;

the peripheral region further includes a common electrode wiring region arranged at a side of the driving circuit region distal to the display region, and a second signal line region arranged between the common electrode wiring region and the driving circuit region;

the array substrate further includes a common electrode wiring, a common electrode connection line and a common electrode arranged in the display region; the common electrode wiring is electrically connected to the common electrode through the common electrode connection line;

the common electrode wiring is located in the common electrode wiring region;

the common electrode connection line traverses the second signal line region and the driving circuit region.

Optionally, the array substrate further includes a plurality of clock signal lines, a first control voltage line, a second control voltage line, a frame reset line and a second low voltage line that are arranged in the second signal line region.

Optionally, the array substrate includes the peripheral region and the display region, the peripheral region includes the driving circuit region; the driver module is arranged in the driving circuit region;

the peripheral region further includes the second signal line region arranged at the side of the driving circuit region distal to the display region;

the array substrate further includes a plurality of clock signal lines arranged in the second signal line region; the clock signal line extends along the first direction, and the plurality of clock signal lines are arranged along the second direction;

the clock signal connection line electrically connected to the clock signal line at a side proximate to the display region includes a winding portion relative to the clock signal connection line electrically connected to the clock signal line proximate to the common electrode wiring region.

Optionally, the first gate line and the second data line intersect to define a sub-pixel region, and the sub-pixel region includes a sub-electrode;

a length of the sub-electrode included in the sub-pixel region farthest from the driver module along the second direction is less than a first length;

the first length is a shortest length of a sub-electrode included in another sub-pixel region along the second direction, the other sub-pixel region is other than the sub-pixel region farthest from the driver module.

Optionally, the array substrate includes a display region and a peripheral region;

the peripheral region includes a first virtual pattern region arranged at a first side of the display region and/or a second virtual pattern region arranged at a fourth side of the display region; the first side and the fourth side are opposite sides;

the array substrate includes a first virtual pattern array arranged in the first virtual pattern region, and/or a second virtual pattern array arranged in the second virtual pattern region;

the first virtual pattern array includes a plurality of first virtual patterns arranged in an array, and the second virtual pattern array includes a plurality of second virtual patterns arranged in an array; the first virtual pattern is configured to support sealant, and the second virtual pattern is configured to support the sealant.

Optionally, the array substrate includes the peripheral region; the peripheral region includes a binding region; the array substrate includes a binding pad arranged in the binding region;

the binding pad is electrically connected to the first data line, and the binding pad is electrically connected to a conductive connection pattern through a via hole, and an edge of the via hole is serrated.

Optionally, the array substrate according to at least one embodiment of the present disclosure further includes a second gate line extending along the second direction;

the first gate line is electrically connected to the second gate line, and the second gate line is electrically connected to the driver module.

Optionally, the first gate line and the second data line intersect to define a sub-pixel region;

a quantity of the first data lines between adjacent driving circuits is greater than or equal to m/(n+2) and less than or equal to m/(n−1);

n is a quantity of the first gate lines, m is a quantity of the second data lines corresponding to the sub-pixel region, and m and n are positives.

Optionally, a quantity of the virtual signal lines is less than a quantity of the first data lines.

In the second aspect, the embodiment of the present disclosure provides a display device, including the above-mentioned array substrate.

### BRIEF DESCRIPTION OF THE DRAWINGS

FIG. 1 is a layout diagram of two driving circuits included in an array substrate and a signal line arranged between the two driving circuits according to the present disclosure;

FIG. 2A is a structural diagram of an array substrate according to at least one embodiment of the present disclosure;

FIG. 2B is a structural diagram of an array substrate according to at least one embodiment of the present disclosure;

FIG. 2C is a structural diagram of an array substrate according to at least one embodiment of the present disclosure;

FIGS. 3A and 3B are structural diagrams of the side region included in an array substrate according to at least one embodiment of the present disclosure;

FIG. 3C is a partial enlarged schematic diagram of the first electrostatic discharge circuit ED1 in FIG. 3A;

FIG. 3D is a circuit diagram according to at least one embodiment of the first electrostatic discharge sub-circuit.

FIG. 4 is a layout diagram of the driving circuit region 30 included in an array substrate according to at least one embodiment of the present disclosure;

FIG. 5 is a layout diagram of the virtual driving circuit region XA included in an array substrate according to at least one embodiment of the present disclosure;

FIG. 6 is a layout diagram of the virtual driving circuit region XA included in an array substrate according to at least one embodiment of the present disclosure;

FIG. 7 is a layout diagram of the virtual driving circuit region XA included in an array substrate according to at least one embodiment of the present disclosure;

FIG. 8 is a layout diagram of the driving circuit region 30, the second signal line region 71 and the common electrode wiring region VMA included in an array substrate according to at least one embodiment of the present disclosure;

FIGS. 9 and 10 are schematic diagrams of a driving circuit that is located in the middle and included in an array substrate according to at least one embodiment of the present disclosure;

FIG. 11 is a schematic diagram of the side region 20 and the virtual driving circuit region XA according to at least one embodiment of the present disclosure;

FIG. 12 is a schematic diagram of a driving circuit that is located at the left side and included in an array substrate according to at least one embodiment of the present disclosure;

FIG. 13 is a schematic diagram of a driving circuit that is located in the middle and included in an array substrate according to at least one embodiment of the present disclosure;

FIG. 14 is a schematic diagram of a driving circuit that is located at the right side and included in an array substrate according to at least one embodiment of the present disclosure;

FIG. 15 is a structural diagram of a driving circuit in an array substrate according to at least one embodiment of the present disclosure;

FIG. 16A is a schematic diagram of the marking of each transistor and capacitor in the driving circuit added on the basis of FIG. 14;

FIG. 16B is a partial enlarged view of the first part of the driving circuit in an order from top to bottom;

FIG. 16C is a partial enlarged view of the second part of the driving circuit in an order from top to bottom;

FIG. 16D is a partial enlarged view of the third part of the driving circuit in an order from top to bottom;

FIG. 16E is a partial enlarged view of the fourth part of the driving circuit in an order from top to bottom.

FIG. 16F is a partial enlarged view of FIG. 16A;

FIG. 17 is a schematic diagram of a common electrode VM included in a sub-pixel region close to the driver module and a pixel electrode PX included in the sub-pixel region close to the driver module;

FIG. 18 is a schematic diagram of a common electrode VM included in a sub-pixel region farthest from the driver module and a pixel electrode PX included in a sub-pixel region farthest from the driver module;

FIG. 19 is a layout diagram of a virtual pattern region included in an array substrate according to the present disclosure;

FIG. 20 is a top view of a via hole region AG occupied by a via hole penetrating through an organic film layer;

FIG. 21 is a cross-sectional view of a via hole in an array substrate according to the present disclosure;

FIG. 22 is a top view of a via hole region AG;

FIG. 23 is a layout diagram of a gate metal layer in FIG. 22.

### DETAILED DESCRIPTION

The technical solutions in the embodiments of the present disclosure will be clearly and thoroughly described below with reference to the accompanying drawings in the embodiments of the present disclosure. Obviously, the described embodiments are only some of the embodiments of the present disclosure, not all of them. Based on the embodiments in the present disclosure, all other embodiments obtained by those of ordinary skill in the art without making creative efforts fall within the scope of the present disclosure.

A transistor used in all embodiments of the present disclosure may be a thin film transistor or a field effect transistor or other devices with the same characteristics. In the embodiments of the present disclosure, in order to distinguish the two electrodes of the transistor except the gate electrode, one of the electrodes is called a first electrode and the other is called a second electrode.

In actual operation, when the transistor is the thin film transistor or the field effect transistor, the first electrode may be a drain electrode and the second electrode may be a source electrode; or, the first electrode may be a source electrode and the second electrode may be a drain electrode.

The array substrate according to the embodiments of the present disclosure includes a base substrate, a first data line, a virtual signal line and a driver module, wherein the first data line, the virtual signal line and the driver module are arranged on the base substrate, wherein the first data line, the virtual signal line and the driver module are arranged in a peripheral region of the array substrate, the peripheral region at least partially surrounds a display region, the display region includes a first gate line extending along a first direction and a second data line extending along a second direction, the first data line is electrically connected to the second data line, and the first direction intersects the second direction;

the driver module is arranged at a first side of the array substrate; the first side is a side arranged in an extension direction of the second data line;

the driver module includes multiple stages of driving circuits; the multiple stages of driving circuits are arranged along the first direction; the driving circuit is configured to provide a driving signal;

the first data line is arranged between at least two adjacent driving circuits, and the first data line is configured to provide a data voltage;

the virtual signal line is further arranged between at least two adjacent driving circuits; the virtual signal line is in a floating state.

In a specific implementation, a first data line, a virtual signal line and a driver module are arranged in the peripheral region of the array substrate, and a first data line and a virtual signal line are arranged between at least two adjacent driving circuits, and the virtual signal line is in a floating state. In the embodiments of the present disclosure, the etching uniformity can be ensured by arranging the virtual signal line.

In at least one embodiment of the present disclosure, the first direction may be a horizontal direction, and the second direction may be a vertical direction, but the present disclosure is not limited thereto.

In at least one embodiment of the present disclosure, the first side may be a side arranged in the extension direction of the second data line; for example, when the extension direction of the second data line is a vertical direction, the first side may be an upper side and/or a lower side.

Optionally, the first data line and the virtual signal line are formed in a same conductive layer.

In a specific implementation, the first data line and the virtual signal line may be formed in the same conductive layer; for example, the first data line and the virtual signal line may both be formed in a source-drain metal layer, but the present disclosure is not limited thereto.

In at least one embodiment of the present disclosure, at least one of the virtual signal lines is arranged between two adjacent first data lines;

the virtual signal line extends along the second direction.

In a specific implementation, the virtual signal line may be arranged between adjacent first data lines, and the virtual signal line may extend along the second direction.

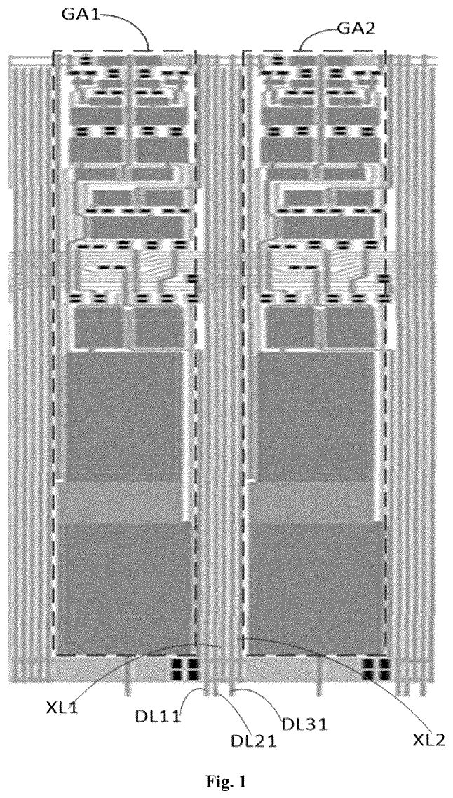

As shown in FIG. 1, a reference sign GA1 denotes a first driving circuit, and a reference sign GA2 denotes a second driving circuit;

the first one of the first data lines DL11, the second one of the first data lines DL21, the third one of the first data lines DL31, a first virtual signal line XL1, and a second virtual signal line XL2 are arranged between the first driving circuit GA1 and the second driving circuit GA2;

the first one of the first data lines DL11, the second one of the first data lines DL21, the third one of the first data lines DL31, the first virtual signal line XL1, and the second virtual signal line XL2 extend in the vertical direction;

the first virtual signal line XL1 is arranged between the first one of the first data lines DL11 and the second one of the first data lines DL21;

the first one of the first data lines DL11, the second one of the first data lines DL21, the third one of the first data lines DL31, the first virtual signal line XL1, and the second virtual signal line XL2 are all formed in the source-drain metal layer.

The display region of the array substrate according to at least one embodiment of the present disclosure further includes a second gate line extending along the second direction;

the first gate line is electrically connected to the second gate line, and the first gate line and the second gate line are arranged in different layers. Optionally, the first gate line may be arranged in a gate metal layer (gate layer), and the second gate line and the second data line of the display region are arranged in a same layer, that is, arranged in the source-drain metal layer (SD layer). The first gate line is electrically connected to the second gate line through a via hole penetrating through an insulating layer, and the second gate line is electrically connected to the driver module.

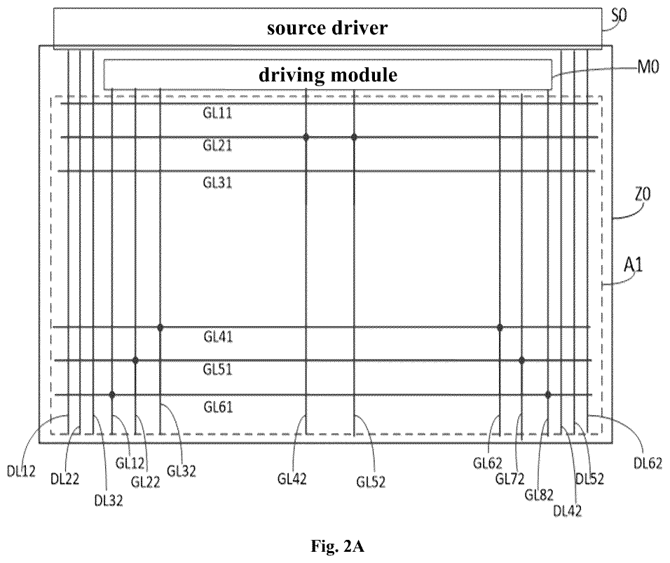

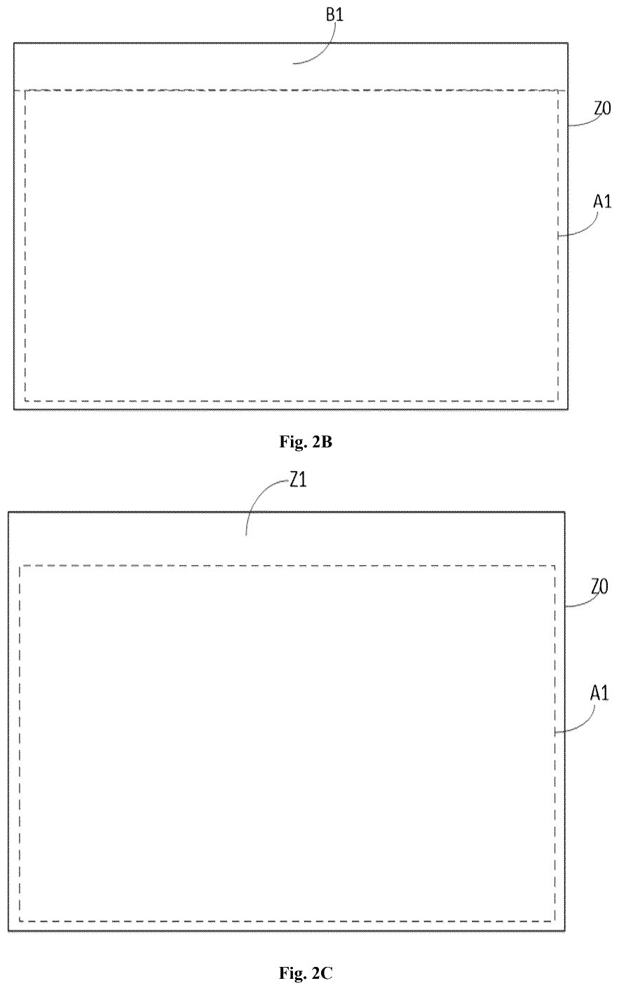

As shown in FIG. 2A, the array substrate may include a first one of the first gate lines GL11, a second one of the first gate lines GL21, a third one of the first gate lines GL31, an (A-2)^{th} one of the first gate lines GL41, an (A-1)^{th} one of the first gate lines GL51, an Ath one of the first gate lines GL61, a first one of the second gate lines GL12, a second one of the second gate lines GL22, a third one of the second gate lines GL32, a (B-2)^{th} one of the second gate lines GL42, a (B-1)^{th} one of the second gate lines GL52, and a B^{th} one of the second gate lines GL62;

the first one of the first gate lines GL11, the second one of the first gate lines GL21, the third one of the first gate lines GL31, the (A-2)^{th} one of the first gate lines GL41, the (A-1)^{th} one of the first gate lines GL51, and the Ath one of the first gate lines GL61 all extend in the horizontal direction;

the first one of the second gate lines GL12, the second one of the second gate lines GL22, the third one of the second gate lines GL32, the (D-1)^{th} one of the second gate lines GL42, the D^{th} one of the second gate lines GL52, the (B-2)^{th} one of the second gate lines GL62, the (B-1)^{th} one of the second gate lines GL72 and the B^{th} one of the second gate lines GL82 all extend in the vertical direction;

A is an integer greater than 5, D is an integer greater than 4, and B is an integer greater than 7.

In FIG. 2A, a reference sign DL12 denotes a first one of the second data lines, a reference sign DL22 denotes a second one of the second data lines, a reference sign DL32 denotes a third one of the second data lines, a reference sign DL42 denotes a (C-2)^{th} one of the second data lines, a reference sign DL52 denotes a (C-1)^{th} one of the second data lines, and a reference sign DL62 denotes a C^{th} one of the second data lines; the C is an integer greater than 5.

In FIG. 2A, FIG. 2B and FIG. 2C, a reference sign Z0 denotes the array substrate.

As shown in FIG. 2A, the DL12, the DL22, the DL32, the DL42, the DL52 and the DL62 all extend in the vertical direction;

each one of the second data lines, each one of the first gate lines and each one of the second gate lines are arranged in a display region A1.

In FIG. 2B, a reference sign B1 denotes the first side, and the driver module MO is arranged at the first side B1;

the first side B1 is a side arranged in the extension direction of each second data line.

As shown in FIG. 2A, the driver module M0 is electrically connected to each of the GL12, the GL22, the GL32, the GL42, the GL52, the GL62, the GL72 and the GL82, and is configured to provide a respective driving signals to each of the GL12, the GL22, the GL32, the GL42, the GL52, the GL62, the GL72 and the GL82;

each first gate line is electrically connected to each second gate line;

the DL12, the DL22, the DL32, the DL42, the DL52 and the DL62 are all electrically connected to a source electrode driver S0 to receive corresponding data voltages from the source electrode driver S0.

In this case, optionally, the first gate line and the second data line in the display region intersect to define a sub-pixel region, and the second gate line and the second data line can be arranged between adjacent sub-pixel regions, or partially overlap with the sub-pixel region in a direction perpendicular to the base substrate, which is not limited here.

In FIG. 2C, a reference sign A1 denotes the display region, and a reference sign Z1 denotes the peripheral region, and the peripheral region Z1 is arranged around the display region A1.

In a specific implementation, a binding pad may be provided at the first side, and the source electrode driver S0 may be electrically connected to each data line through the binding pad, or the binding pad may be electrically connected to a flexible circuit board, and the source electrode driver is arranged on the flexible circuit board, and then the second data line provides a data signal.

Optionally, the first gate line and the second data line intersect to define a sub-pixel region;

the number of first data lines between adjacent driving circuits is greater than or equal to m/(n+2) and less than or equal to m/(n−1);

n is the quantity of the first gate lines, and m is the quantity of second data lines corresponding to the sub-pixel region;

m and n are positive integers.

In at least one embodiment of the present disclosure, the quantity of the virtual signal lines is less than the quantity of the first data lines, so that a narrow bezel can be achieved while ensuring etching uniformity.

Optionally, the quantity of the first data lines may be 3, and the quantity of the virtual signal lines may be 2, but the present disclosure is not limited thereto.

In at least one embodiment of the present disclosure, the peripheral region includes a driving circuit region and a side region; the driver module is arranged in the driving circuit region;

the side region is arranged on two opposite sides of the arrangement direction of the driving circuit region, that is, the side region is arranged at two opposite sides extending in the first direction;

the side region includes a first signal line region and a first electrostatic discharge region; the array substrate further includes a plurality of clock signal lines arranged in the first signal line region, and a first electrostatic discharge circuit arranged in the first electrostatic discharge region;

the first electrostatic discharge circuit is electrically connected to the clock signal line, and is configured to provide electrostatic protection for the clock signal line.

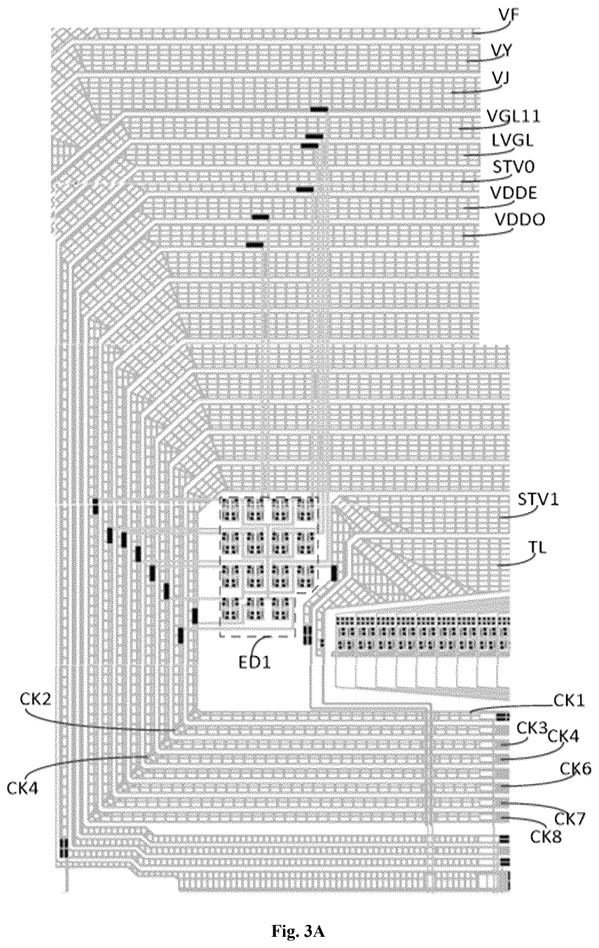

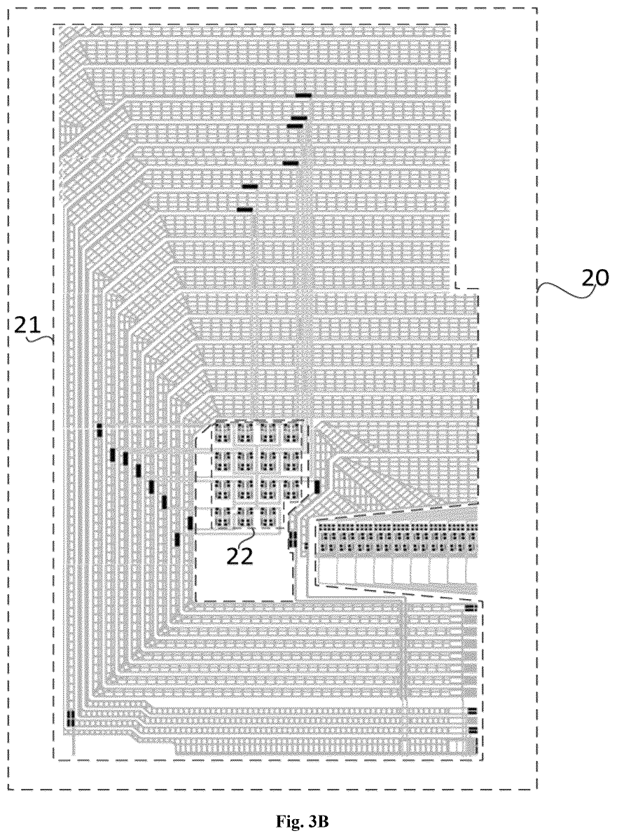

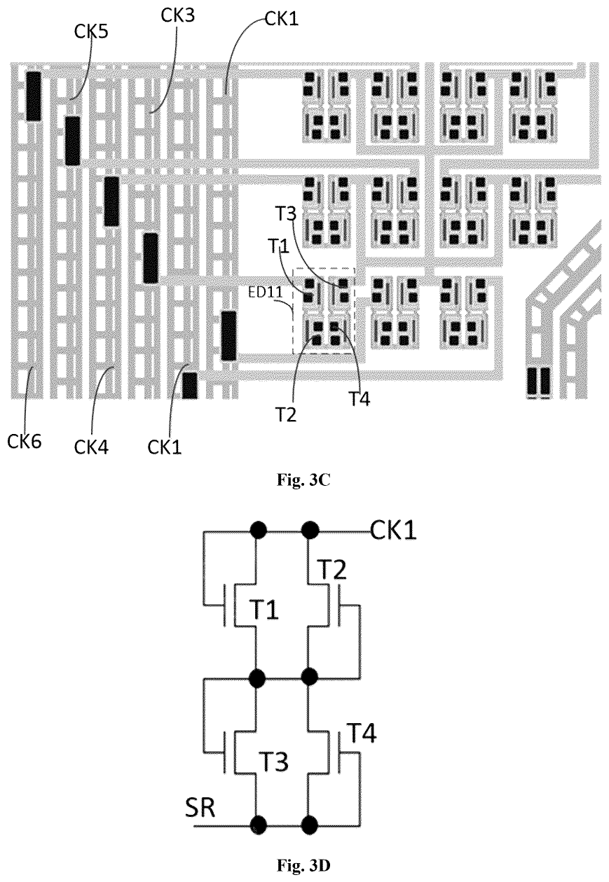

In FIG. 3B, the region 20 is a side region;

the side region 20 includes a first signal line region 21 and a first electrostatic discharge region 22;

a plurality of signal lines is arranged in the first signal line region 21, and as shown in FIG. 3A, a first electrostatic discharge circuit ED1 is arranged in the first electrostatic discharge region 22.

In FIG. 3A, a reference sign CK1 denotes a first clock signal line, a reference sign CK2 denotes a second clock signal line, a reference sign CK3 denotes a third clock signal line, a reference sign CK4 denotes a fourth clock signal line, a reference sign CK5 denotes a fifth clock signal line, a reference sign CK6 denotes a sixth clock signal line, a reference sign CK7 denotes a seventh clock signal line, and a reference sign CK8 denotes an eighth clock signal line (taking eight clock signal lines as an example, but the present disclosure is not limited thereto);

a reference sign VGL11 denotes a first one of first low voltage lines, a reference sign LVGL denotes a second low voltage line, a reference sign STV0 denotes a frame reset line, a reference sign VDDE denotes a second control voltage line, a reference sign VDDO denotes a first control voltage line, and a reference sign STV1 denotes an initial voltage line.

In at least one embodiment shown in FIG. 3A, each clock signal line, the first one of the low voltage lines VGL11, the second low voltage line LVGL, the frame reset line STV0, the first control voltage line VDDO, the second control voltage line VDDE and the initial voltage line STV1 may be formed in the gate metal layer, and these signal lines may be electrically connected to the first electrostatic discharge circuit through a cross-line, and the cross-line may be in a same electrode layer as a pixel electrode or a common electrode in the display region, such as an Indium Tin Oxide (ITO) layer, but the present disclosure is not limited thereto.

In at least one embodiment of the present disclosure, the array substrate further includes the first one of the first low voltage lines, the second low voltage line, the frame reset line, the first control voltage line, the second control voltage line and the initial voltage line arranged in the first signal line region;

the first electrostatic discharge circuit is further electrically connected to each of the first one of the first low voltage lines, the second low voltage line, the frame reset line, the first control voltage line, the second control voltage line and the initial voltage line, and is configured to provide electrostatic protection for the first one of the first low voltage lines, the second low voltage line, the frame reset line, the first control voltage line, the second control voltage line and the initial voltage line;

the first one of the first low voltage lines is configured to provide a first low voltage signal, the frame reset line is configured to provide a frame reset signal, the first control voltage line is configured to provide a first control voltage, the second control voltage line is configured to provide a second control voltage, and the initial voltage line is configured to provide an initial voltage to a gate electrode driving circuit.

As shown in FIG. 3A, the first electrostatic discharge circuit ED1 is electrically connected to each of the first one of the first low voltage lines VGL11, the second low voltage line LVGL, the frame reset line STV0, the second control voltage line VDDE, the first control voltage line VDDO and the initial voltage line STV1, and is configured to provide electrostatic protection for the first one of the first low voltage lines VGL, the second low voltage line LVGL, the frame reset line STV0, the second control voltage line VDDE, the first control voltage line VDDO and the initial voltage line STV1.

The first one of the first low voltage lines VGL11 is configured to provide a first low voltage signal, the frame reset line STV0 is configured to provide a frame reset signal, the second control voltage line VDDE is configured to provide a second control voltage, the first control voltage line VDDO is configured to provide a first control voltage, and the initial voltage line STV1 is configured to provide an initial voltage.

In at least one embodiment of the present disclosure, the clock signal line, the second low voltage line, the frame reset line, the first control voltage line and the second control voltage line are arranged at the first side, the second side and the third side of the first electrostatic discharge circuit; the first one of the first low voltage lines is arranged at the first side and the second side of the first electrostatic discharge circuit; the initial voltage line is arranged at the fourth side of the first electrostatic discharge circuit;

the first side and the fourth side are opposite sides, and the second side and the third side are opposite sides.

Optionally, the first side may be the left side, the second side may be the upper side, the third side may be the lower side, and the fourth side may be the right side, but the present disclosure is not limited thereto

As shown in FIG. 3A, each clock signal line may be arranged at the left side, upper side and lower side of the first electrostatic discharge circuit ED1, the first one of the first low voltage lines VGL11 may be arranged at the left side and upper side of the first electrostatic discharge circuit ED1; the initial voltage line STV1 may be arranged at the right side of the first electrostatic discharge circuit;

the second low voltage line LVGL, the frame reset line STV0, the first control voltage line VDDO and the second control voltage line VDDE are arranged at the left side, upper side and lower side of the first electrostatic discharge circuit ED1. Referring further to FIG. 3A, in this case, the clock signal line and the first electrostatic discharge circuit are electrically connected through the cross-line, and the cross-line extends along the first direction, that is, the part of the clock signal line at the left side of the first electrostatic discharge circuit is electrically connected to the first electrostatic discharge circuit through the cross-line, and other signal lines (including the second low voltage line LVGL, the frame reset line STV0, the first control voltage line VDDO and the second control voltage line VDDE) are electrically connected to the first electrostatic discharge circuit through the cross-line, and the wide line extends along the second direction, that is, the part of the other signal lines at the upper side of the first electrostatic discharge circuit are electrically connected to the first electrostatic discharge circuit through the cross-line. In addition, the initial voltage line STV1 is electrically connected to the first electrostatic discharge circuit through the cross-line. The cross-line extends along the first direction, that is, the part of the initial voltage line STV1 at the right side of the first electrostatic discharge circuit is electrically connected to the first electrostatic discharge circuit through the cross-line. In this case, the electrical connection with the first electrostatic discharge circuit is realized by leading out the cross-line from the left side, the top side and the right side respectively including three parts of signal lines, so that the first electrostatic discharge circuit is arranged within a region surrounded by the signal lines, which can reduce the space occupied by the first electrostatic discharge circuit, thereby further achieving a narrow bezel effect.

In FIG. 3A, a reference sign VJ denotes a proximal signal line of the common electrode, a reference sign VY denotes a distal signal line of the common electrode, and a reference sign VF denotes a distal feedback line of the common electrode;

the proximal signal line of the common electrode VJ is electrically connected to the first electrostatic discharge circuit ED1, and the first electrostatic discharge circuit ED1 is configured to provide electrostatic protection for the proximal signal line of the common electrode VJ;

a reference sign TL denotes a test line.

In at least one embodiment shown in FIG. 3A, the proximal signal line of the common electrode VJ, the distal signal line of the common electrode VY, the distal feedback line of the common electrode VF and the test line TL may all be formed in the gate metal layer, but the present disclosure is not limited thereto.

In at least one embodiment shown in FIG. 3A, the distal signal line of the common electrode VY is electrically connected to a distal end of the common electrode voltage line to provide a common electrode voltage to the distal end of the common electrode voltage line;

the proximal signal line of the common electrode VJ is electrically connected to a proximal end of the common electrode voltage line to provide a common electrode voltage to the proximal end of the common electrode voltage line;

the distal feedback line of the common electrode VF is electrically connected to the distal end of the common electrode voltage line to receive a signal fed back from the distal end of the common electrode voltage line;

the distal end of the common electrode voltage line is an end of the common electrode voltage line distal to the first side;

the proximal end of the common electrode voltage line is an end of the common electrode voltage line proximate to the first side.

In at least one embodiment shown in FIG. 3A, the test line TL is electrically connected to an output end of the last-stage driving circuit included in the driver module, and the test line TL is further electrically connected to a driving integrated circuit, which receives a signal from the test line TL to determine whether the driving signal provided by the output end of the last-stage driving circuit is accurate.

FIG. 3C is a partial enlarged schematic diagram of the first electrostatic discharge circuit ED1 in FIG. 3A. The first electrostatic discharge circuit ED1 includes multiple electrostatic discharge sub-circuits, and the structures of the multiple electrostatic discharge sub-circuits may be the same; but the present disclosure is not limited thereto; in actual operation, the structures of at least two of the multiple electrostatic discharge sub-circuits may also be different from each other;

as shown in FIG. 3C and FIG. 3D, the first electrostatic discharge sub-circuit ED11 may include a first protection transistor T1, a second protection transistor T2, a third protection transistor T3 and a fourth protection transistor T4; when the electrostatic discharge sub-circuit is configured to provide electrostatic protection for a first clock signal line CK1,

a gate electrode of the first protection transistor T1 and a first electrode of the first protection transistor T1 can both be electrically connected to the first clock signal line CK1. A second electrode of the first protection transistor T1 is electrically connected to the second electrode of the second protection transistor T2;

a gate electrode of the second protection transistor T2 is electrically connected to the second electrode of the second protection transistor T2; a first electrode of the second protection transistor T2 is electrically connected to the first clock signal line CK1;

a gate electrode of the third protection transistor T3 and a first electrode of the third protection transistor T3 are both electrically connected to the gate electrode of the second protection transistor T2;

a gate electrode of the fourth protection transistor T4 is electrically connected to a second electrode of the fourth protection transistor T4, and a first electrode of the fourth protection transistor T4 is electrically connected to the gate electrode of the second protection transistor T2;

a second electrode of the third protection transistor T3 and the second electrode of the fourth protection transistor T4 are both electrically connected to a Static Ring (SR).

Optionally, the second electrode of the third protection transistor T3 and the second electrode of the fourth protection transistor T4 may also be replaced by being electrically connected to a common electrode voltage end;

the gate electrode of the first protection transistor T1 and the first electrode of the first protection transistor T1 may be replaced by other clock signal lines, the first one of the first low voltage lines VGL11, the second low voltage line LVGL, the frame reset line STV0, the second control voltage line VDDE, the first control voltage line VDDO or the initial voltage line STV1, but the present disclosure is not limited thereto.

In at least one embodiment of the present disclosure, the array substrate includes a driving circuit region and a display region, the driver module is arranged in the driving circuit region; the driving circuit region includes a wiring region;

the array substrate further includes a second one of the first low voltage lines arranged between the driving circuit region and the display region, and a cascade line arranged in the wiring region (the cascade line includes a carry signal line and a reset signal line. The carry signal line is configured to provide a carry signal from an upper-level Gate On Array (GOA) circuit (the GOA circuit arranged on the array substrate) to an input module of a lower-level GOA circuit, while the reset signal line is configured to provide a reset signal from the lower-level GOA circuit to a reset module of the upper-level GOA. For example, the reset signal may be configured to reset a pull-up node or the output end of the GOA circuit);

the cascade line is a signal line for cascading the multiple stages of driving circuits included in the driver module; the second one of the first low voltage lines is configured to provide a first low voltage signal;

an orthographic projection of the virtual signal line onto the base substrate overlaps at least partially with an orthographic projection of the cascade line onto the base substrate;

the orthographic projection of the virtual signal line onto the base substrate overlaps at least partially with an orthographic projection of the second one of the first low voltage lines onto the base substrate.

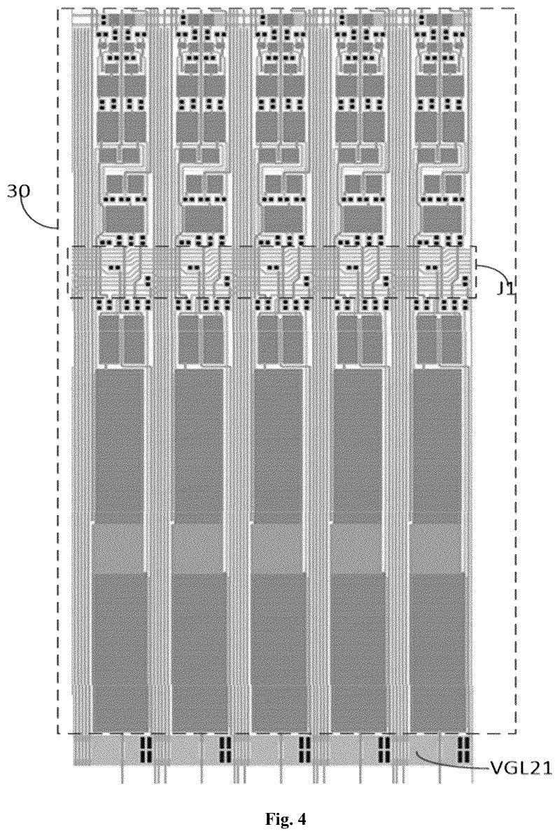

As shown in FIG. 4, a driving circuit included in a driver module is arranged in the driving circuit region 30, and the region J1 is a wiring region;

the array substrate further includes a second one of the first low voltage lines VGL21 arranged between the driving circuit region 30 and the display region;

the second one of the first low voltage lines VGL21 is configured to provide a first low voltage signal.

In at least one embodiment of the present disclosure, the first one of the first low voltage lines VGL11 and the second one of the first low voltage lines VGL21 may be electrically connected to each other.

In at least one embodiment of the present disclosure, the peripheral region includes a virtual driving circuit region; the array substrate includes a virtual driver module arranged in the virtual driving circuit region, and the virtual driving circuit region is arranged between the side region and the display region;

the virtual driver module includes a plurality of virtual driving circuits arranged along the first direction;

the virtual driving circuit includes a virtual driving output end and a virtual input end;

the virtual input end of the virtual driving circuit is disconnected from a virtual driving output end of another virtual driving circuit included in the virtual driver module other than the virtual driving circuit. That is, the virtual driving region is the region where the virtual driving circuit is arranged, and the cascade line in the wiring region does not cascade the GOA circuit included in the virtual driver module, resulting in a disconnected state. A virtual driving circuit is arranged, so as to achieve the stability of a preparation process with the driving circuit configured to provide a gate signal to the second gate line in the display region.

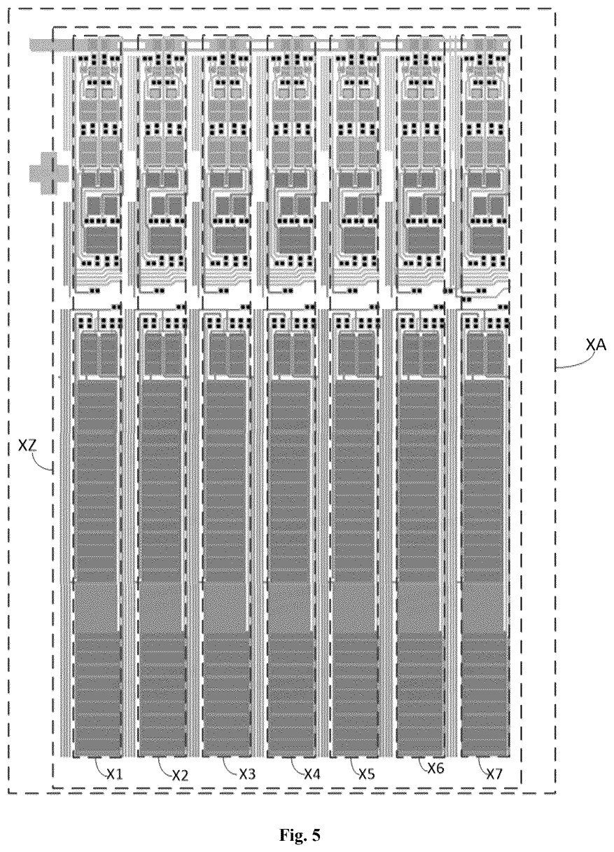

In FIG. 5, a reference sign XA denotes a virtual driving circuit region, and the virtual driving circuit region is arranged between a side region and a display region;

in FIG. 5, a reference sign XZ denotes a virtual driver module, and the virtual driver module XZ includes a plurality of virtual driving circuits arranged in a horizontal direction;

in FIG. 5, a reference sign X1 denotes a first virtual driving circuit, a reference sign X2 denotes a second virtual driving circuit, a reference sign X3 denotes a third virtual driving circuit, a reference sign X4 denotes a fourth virtual driving circuit, a reference sign X5 denotes a fifth virtual driving circuit, a reference sign X6 denotes a sixth virtual driving circuit, and a reference sign X7 denotes a seventh virtual driving circuit.

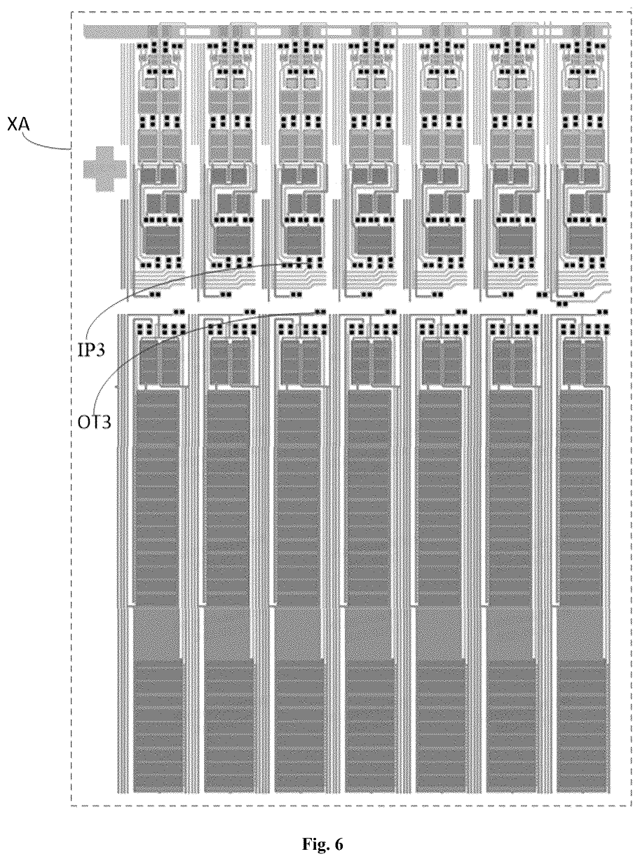

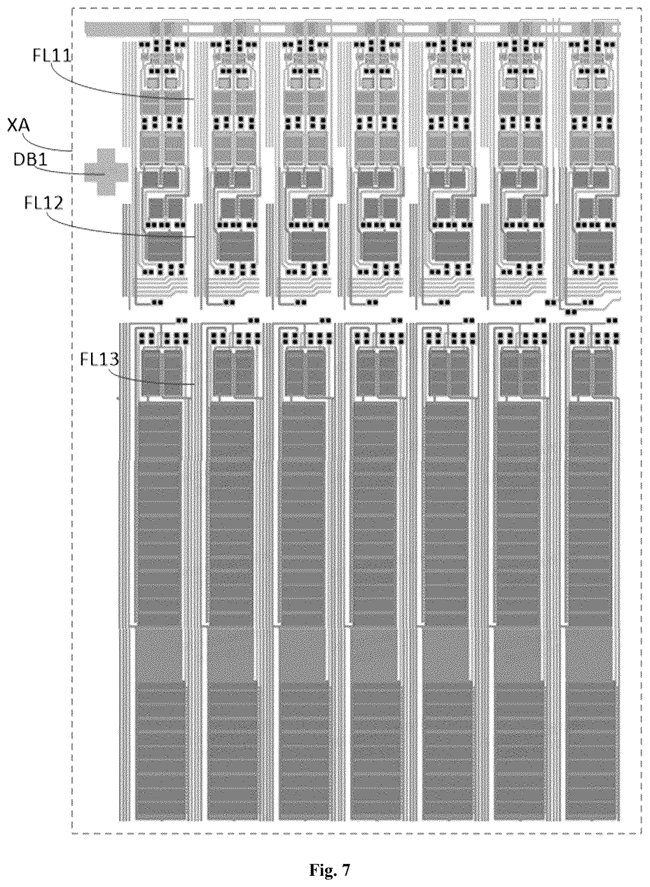

In FIG. 6, a reference sign IP3 denotes a virtual input end of the X3, and a reference sign OT3 denotes a virtual driving output end of the X3.

As shown in FIG. 5 and FIG. 6, the virtual input end included in the virtual driving circuit is disconnected from the virtual driving output end included in the virtual driver module.

Optionally, the array substrate further includes a floating signal line arranged between adjacent virtual driving circuits to maintain the etching uniformity in the preparation process;

the floating signal line is in a floating state.

In a specific implementation, the array substrate further includes a floating signal line in a floating state arranged between adjacent virtual driving circuits.

As shown in FIG. 7, a reference sign FL11 denotes a first floating signal line part included in the first floating signal line, a reference sign FL12 denotes a second floating signal line part included in the first floating signal line, and a reference sign FL13 denotes a third floating signal line part included in the first floating signal line;

the first floating signal line is arranged between the first virtual driving circuit X1 and the second virtual driving circuit X2.

As shown in FIG. 7, a floating signal line is further arranged at the left side of the first virtual driving circuit X1;

a cross-shaped alignment mark DB1 is arranged at the left side of the first virtual driving circuit X1. To save the bezel space, the alignment mark DB1 is designed close to the first virtual driving circuit X1, so the upper part of the floating signal line located in the wiring region is divided into two parts.

In at least one embodiment of the present disclosure, the array substrate includes the peripheral region and the display region, the peripheral region includes a driving circuit region; the driver module is arranged in the driving circuit region;

the peripheral region further includes a common electrode wiring region arranged at a side of the driving circuit region distal to the display region, and a second signal line region arranged between the common electrode wiring region and the driving circuit region;

the array substrate further includes a common electrode wiring, a common electrode connection line and a common electrode arranged in the display region; the common electrode wiring is electrically connected to the common electrode through the common electrode connection line;

the common electrode wiring is located in the common electrode wiring region;

the common electrode connection line traverses the second signal line region and the driving circuit region.

Optionally, the array substrate further includes a plurality of clock signal lines, a first control voltage line, a second control voltage line, a frame reset line and a second low voltage line that are arranged in the second signal line region.

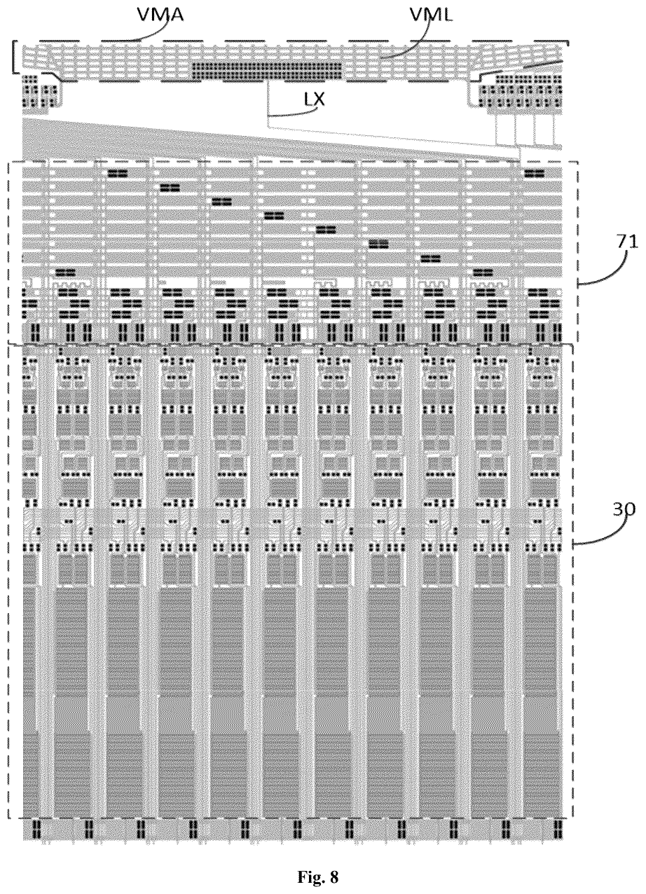

As shown in FIG. 8, the peripheral region includes a driving circuit region 30, and the driving circuit included in the driver module is arranged in the driving circuit region 30;

the peripheral region further includes a common electrode wiring region VMA arranged at the side of the driving circuit region 30 distal to the display region, and a second signal line region 71 arranged between the common electrode wiring region VMA and the driving circuit region 30;

the array substrate further includes a common electrode line VML, a common electrode connection line LX and a common electrode arranged in the display region;

the common electrode line VML is electrically connected to the common electrode through the common electrode connection line LX;

the common electrode line VML is arranged in the common electrode wiring region VMA;

the common electrode connection line LX traverses the second signal line region 71 and the driving circuit region 30, and then extends to the display region.

In at least one embodiment shown in FIG. 8, the common electrode line VML may be formed in the gate metal layer, and the common electrode connection line LX may be formed in the source-drain metal layer, but the present disclosure is not limited thereto, and the two may be electrically connected through an electrode layer deposited in a via hole of the insulating layer.

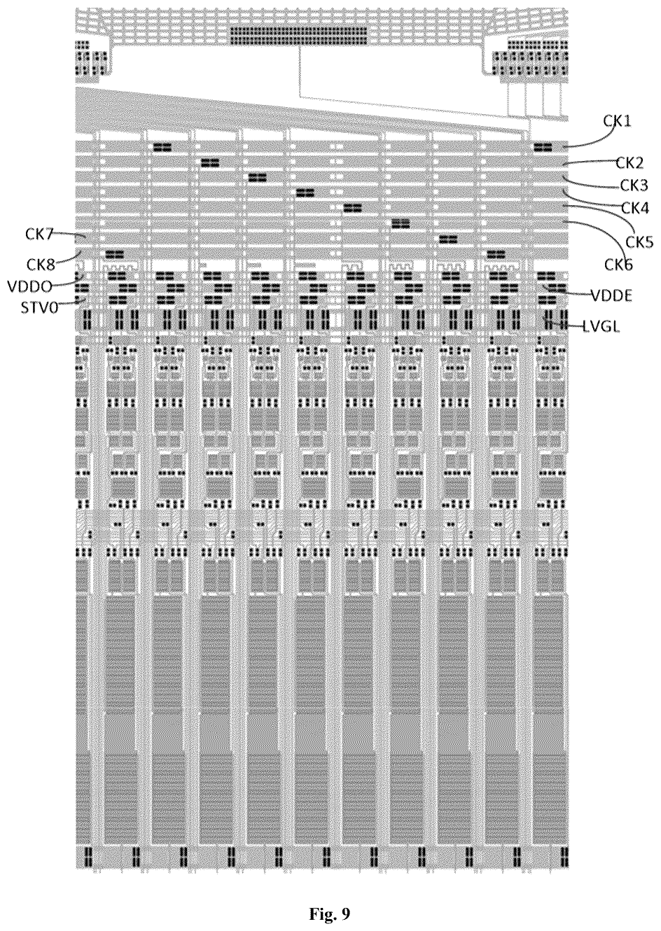

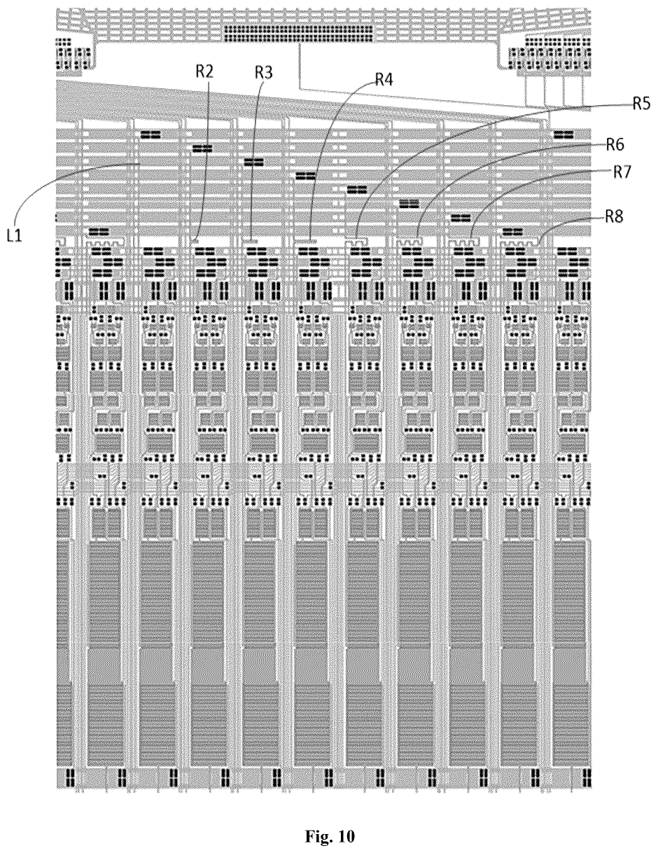

In FIG. 9, a reference sign CK1 denotes a first clock signal line, a reference sign CK2 denotes a second clock signal line, a reference sign CK3 denotes a third clock signal line, a reference sign CK4 denotes a fourth clock signal line, a reference sign CK5 denotes a fifth clock signal line, a reference sign CK6 denotes a sixth clock signal line, a reference sign CK7 denotes a seventh clock signal line, and a reference sign CK8 denotes an eighth clock signal line;

a reference sign VDDO denotes a first control voltage line, a reference sign VDDE denotes a second control voltage line, a reference sign STV0 denotes a frame reset line, and a reference sign LVGL denotes a second low voltage line.

In at least one embodiment of the present disclosure, the array substrate includes the peripheral region and the display region, the peripheral region includes the driving circuit region; the driver module is arranged in the driving circuit region;

the peripheral region further includes the second signal line region arranged at the side of the driving circuit region distal to the display region;

the array substrate further includes a plurality of clock signal lines arranged in the second signal line region; the clock signal line extends along the first direction, and the plurality of clock signal lines are arranged along the second direction;

the clock signal connection line electrically connected to the clock signal line at a side proximate to the display region includes a winding portion relative to the clock signal connection line electrically connected to the clock signal line proximate to the common electrode wiring region.

As shown in FIG. 8, the first clock signal line CK1, the second clock signal line CK2, the third clock signal line CK3, the fourth clock signal line CK4, the fifth clock signal line CK5, the sixth clock signal line CK6, the seventh clock signal line CK7 and the eighth clock signal line CK8 are arranged in the second signal line region 71;

each of the clock signal lines extends in the horizontal direction, and each of the clock signal lines is arranged in the vertical direction;

the clock signal connection line electrically connected to the clock signal line at a side proximate to the display region includes a winding portion relative to the clock signal connection line electrically connected to the clock signal line proximate to the common electrode wiring region, to enable compensation such that the length of the connection line between each clock signal line and the driving circuit is approximately equal.

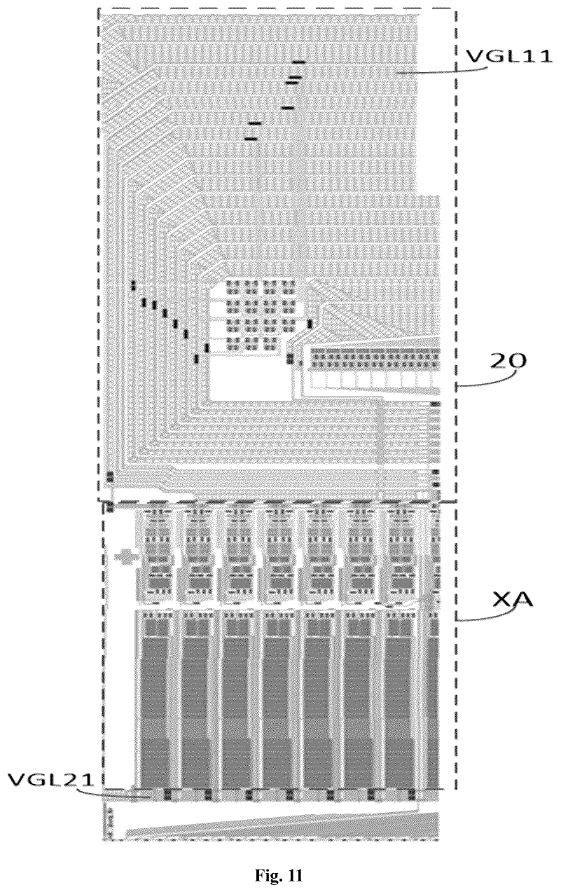

In at least one embodiment shown in FIG. 9 and FIG. 10, the CK1 is the clock signal line proximate to the common electrode wiring region, and the CK1 is electrically connected to the first clock signal connection line L1; the first clock signal connection line L1 does not have a winding portion; optionally, the clock signal line is arranged in the gate metal layer, and the connection line L1 is arranged in the source-drain metal layer, and the two can be electrically connected through the electrode layer deposited in the via hole of the insulating layer. The connection line and the clock signal line overlap vertically to the base substrate, and at the overlapping position, the clock signal line at least partially has a hollow portion to reduce the coupling capacitance between the connection line and the clock signal line.

The CK8 is the clock signal line proximate to the display region, the CK8 is electrically connected to an eighth clock signal connection line, and the eighth clock signal connection line includes the eighth winding portion R8;

the CK7 is the second closest clock signal line to the display region, the CK7 is electrically connected to the seventh clock signal connection line, and the seventh clock signal connection line includes the seventh winding portion R7;

the CK6 is the third closest clock signal line to the display region, the CK6 is electrically connected to the sixth clock signal connection line, and the sixth clock signal connection line includes the sixth winding portion R6;

the CK5 is the fourth closest clock signal line to the display region, the CK5 is electrically connected to the fifth clock signal connection line, and the fifth clock signal connection line includes the fifth winding portion R5;

the CK4 is the fifth closest clock signal line to the display region. The clock signal line of the CK4 is electrically connected to the fourth clock signal connection line, and the fourth clock signal connection line includes the fourth winding portion R4;

the CK3 is the sixth closest clock signal line to the display region, the CK3 is electrically connected to the third clock signal connection line, and the third clock signal connection line includes the third winding portion R3;

the CK2 is the seventh closest clock signal line to the display region, the CK2 is electrically connected to the second clock signal connection line L2, and the second clock signal connection line includes the second winding portion R2;

the length of the R8 is greater than the length of R7, the length of the R7 is greater than the length of the R6, the length of the R6 is greater than the length of the R5, the length of the R5 is greater than the length of the R4, the length of the R4 is greater than the length of the R3, and the length of R3 is greater than the length of the R2.

In at least one embodiment shown in FIG. 10, since the CK2, the CK3, the CK4, the CK5, the CK6, the CK7, and the CK8 are arranged in sequence along a direction toward the display region, the length of the R8 is arranged to be greater than the length of the R7, the length of the R7 is arranged to be greater than the length of the R6, the length of the R6 is arranged to be greater than the length of the R5, the length of the R5 is arranged to be greater than the length of the R4, the length of the R4 is arranged to be greater than the length of the R3, and the length of the R3 is arranged to be greater than the length of the R2. This ensures that the impedance of the connection line between each clock signal line and the driving circuit is approximately the same to balance the impedance.

FIG. 11 is a schematic diagram of the side region 20 and the virtual driving circuit region XA according to at least one embodiment of the present disclosure.

The virtual driving circuit region XA is arranged at the side of the side region 20 proximate to the display region.

In FIG. 11, a reference sign VGL11 denotes a first one of the first low voltage lines, and a reference sign VGL21 denotes a second one of the first low voltage lines. As shown in FIG. 11, the VGL11 and the VGL21 can be electrically connected through the conductive line at the left side.

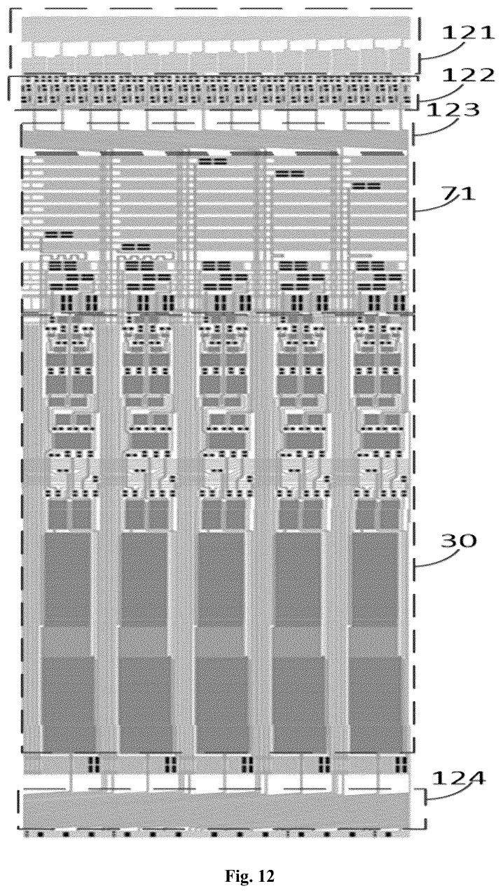

FIG. 12 is a schematic diagram of a driving circuit located at the left side included in an array substrate according to at least one embodiment of the present disclosure.

In FIG. 12, a reference sign 121 denotes a third signal line region, a reference sign 122 denotes a second electrostatic discharge region, a reference sign 123 denotes a fourth signal line region, a reference sign 71 denotes a second signal line region, a reference sign 30 denotes a driving circuit region, and a reference sign 124 denotes a fifth signal line region.

As shown in FIG. 12, the third signal line region 121, the second electrostatic discharge region 122, the fourth signal line region 123, the second signal line region 71, the driving circuit region 30 and the fifth signal line region 124 are arranged in sequence along the direction toward the display region.

In at least one embodiment shown in FIG. 12, the third signal line region 121 is provided with a first data line formed in the gate metal layer;

the second electrostatic discharge region 122 is provided with an electrostatic discharge circuit, and the electrostatic discharge circuit is configured to provide electrostatic protection for the data line;

the fourth signal line region 123 is provided with a first data line formed in the source-drain metal layer;

the second signal line region 71 is provided with a clock signal line, a first control voltage line, a second control voltage line and a second low voltage line formed in the gate metal layer;

the driving circuit region 30 is provided with a plurality of driving circuits arranged in a horizontal direction, and the first data line formed in the source-drain metal layer passes between two adjacent driving circuits to extend to the display region;

the fifth signal line region 124 is provided with a first data line formed in the source-drain metal layer.

The third signal line region 121 is also a fan-out region, and a binding pad can be provided in the fan-out region, and the binding pad is electrically connected to the source electrode driver or is electrically connected to the binding region of the flexible circuit board.

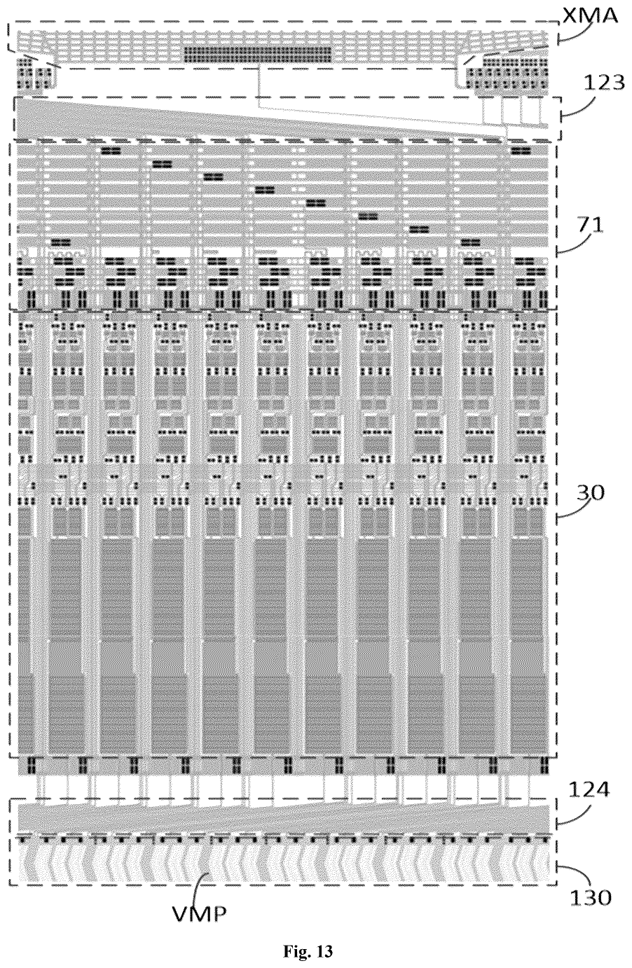

FIG. 13 is a schematic diagram of a driving circuit that is located in the middle and included in an array substrate according to at least one embodiment of the present disclosure.

In FIG. 13, a reference sign VMA denotes a common electrode wiring region, a reference sign 123 denotes a fourth signal line region, a reference sign 71 denotes a second signal line region, a reference sign 30 denotes a driving circuit region, and a reference sign 123 denotes a fourth signal line region.

As shown in FIG. 13, the common electrode wiring region VMA, the fourth signal line region 123, the second signal line region 71, the driving circuit region 30 and the fifth signal line region 124 are arranged in sequence along the direction toward the display region.

In at least one embodiment shown in FIG. 13, a common electrode wiring formed in the gate metal layer is provided in the common electrode wiring region VMA;

a first data line formed in the source-drain metal layer is provided in the fourth signal line region 123; a common electrode connection line formed in the source-drain metal layer and a first data line formed in the source-drain metal layer are provided in the second signal line region 71;

a plurality of driving circuits arranged in the horizontal direction is provided in the driving circuit region 30, and the first data line formed in the source-drain metal layer and the common electrode connection line passes between two adjacent driving circuits to extend to the display region;

a first data line formed in the source-drain metal layer is provided in the fifth signal line region 124.

In FIG. 13, a reference sign 130 denotes a display region, and a common electrode VMP is provided in the display region, and the common electrode VMP can be electrically connected to the common electrode wiring.

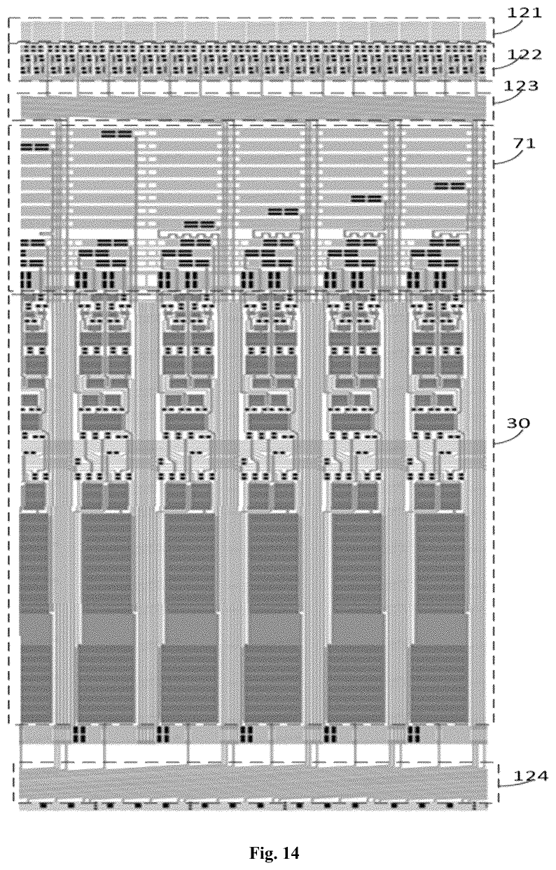

FIG. 14 is a schematic diagram of a driving circuit that is located at the right side and included in an array substrate according to at least one embodiment of the present disclosure.

As shown in FIG. 14, a reference sign 121 denotes a third signal line region, a reference sign 122 denotes a second electrostatic discharge region, a reference sign 123 denotes a fourth signal line region, a reference sign 71 denotes a second signal line region, a reference sign 30 denotes a driving circuit region, and a reference sign 124 denotes a fifth signal line region.

As shown in FIG. 14, the third signal line region 121, the second electrostatic discharge region 122, the fourth signal line region 123, the second signal line region 71, the driving circuit region 30 and the fifth signal line region 124 are arranged in sequence along the direction toward the display region.

In at least one embodiment shown in FIG. 14, the third signal line region 121 is provided with a first data line formed in the gate metal layer;

the second electrostatic discharge region 122 is provided with an electrostatic discharge circuit, and the electrostatic discharge circuit is configured to provide electrostatic protection for the data line;

the fourth signal line region 123 is provided with a first data line formed in the source-drain metal layer;

the second signal line region 71 is provided with a clock signal line, a first control voltage line, a second control voltage line and a second low voltage line formed in the gate metal layer;

the driving circuit region 30 is provided with a plurality of driving circuits arranged in a horizontal direction, and the first data line formed in the source-drain metal layer passes between two adjacent driving circuits to extend to the display region;

the fifth signal line region 124 is provided with a first data line formed in the source-drain metal layer.

The third signal line region 121 is also a fan-out region, and a binding pad can be provided in the fan-out region, and the binding pad is electrically connected to the source electrode driver.

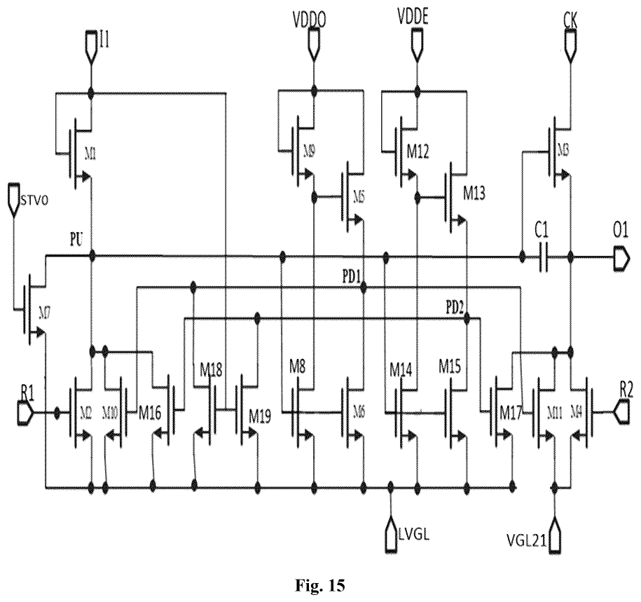

FIG. 15 is a structural diagram of a driving circuit in an array substrate according to at least one embodiment of the present disclosure.

As shown in FIG. 15, at least one embodiment of the driving circuit may include a first transistor M1, a second transistor M2, a third transistor M3, a fourth transistor M4, a fifth transistor M5, a sixth transistor M6, a seventh transistor M7, an eighth transistor M8, a ninth transistor M9, a tenth transistor M10, an eleventh transistor M11, a twelfth transistor M12, a thirteenth transistor M13, a fourteenth transistor M14, a fifteenth transistor M15, a sixteenth transistor M16, a seventeenth transistor M17, an eighteenth transistor M18, a nineteenth transistor M19, and a first capacitor C1. The connection relationships of the transistors in the GOA circuit of this case can be referred to in FIG. 15. For example, the gate electrode of the third transistor M3 is electrically connected to the pull-up node, the first electrode of the third transistor M3 is electrically connected to the clock signal line CK, the second electrode of the third transistor M3 is electrically connected to the driving signal output end O1, the gate electrode of the seventh transistor M7 is electrically connected to the frame reset line STV0, the first electrode of the seventh transistor M7 is electrically connected to the pull-up node PU, the second electrode of the seventh transistor M7 is electrically connected to the second low voltage line LVGL, and the connection relationships of other transistors can be referred to in FIG. 5, which will not be described in detail here.

In FIG. 15, a reference sign I1 denotes an input end, a reference sign STV0 denotes a frame reset line (configured to reset the GOA circuit before a frame), a reference sign R1 denotes a first reset end (the first reset end R1 of the upper GOA circuit may be electrically connected to the driving signal output end O1 of the lower GOA circuit), a reference sign PU denotes a pull-up node, a reference sign PD1 denotes a first pull-down node, a reference sign PD2 denotes a second pull-down node, a reference sign VDDO denotes a first control voltage line, a reference sign VDDE denotes a second control voltage line, a reference sign CK denotes a clock signal line, a reference sign VGL21 denotes a second one of the first low voltage lines, a reference sign O1 denotes a driving signal output end, and a reference sign RST denotes a second reset end.

In at least one embodiment of the present disclosure, the second one of the first low voltage lines VGL21 and the first one of the first low voltage lines VGL11 may be electrically connected to each other.

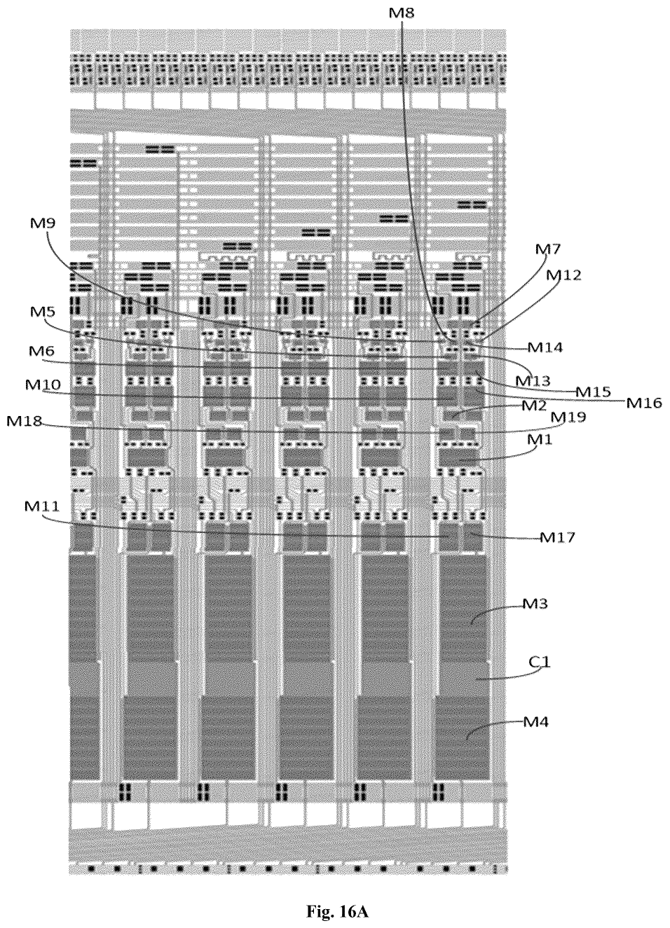

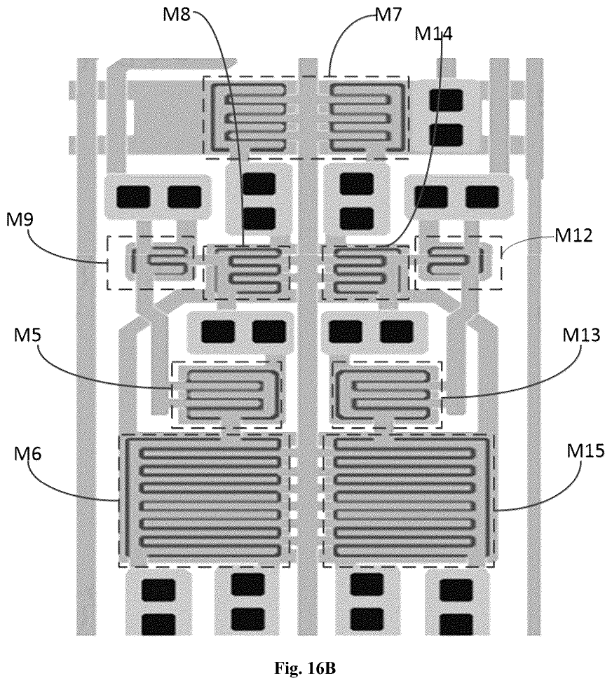

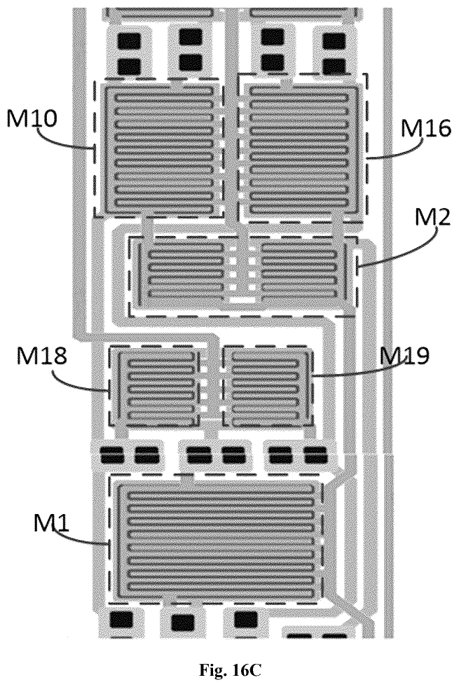

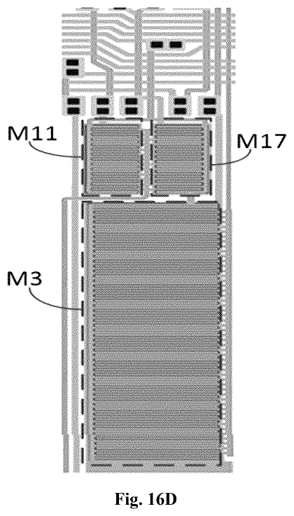

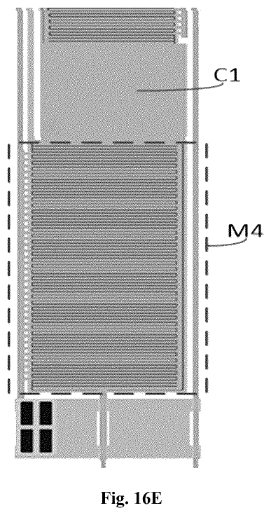

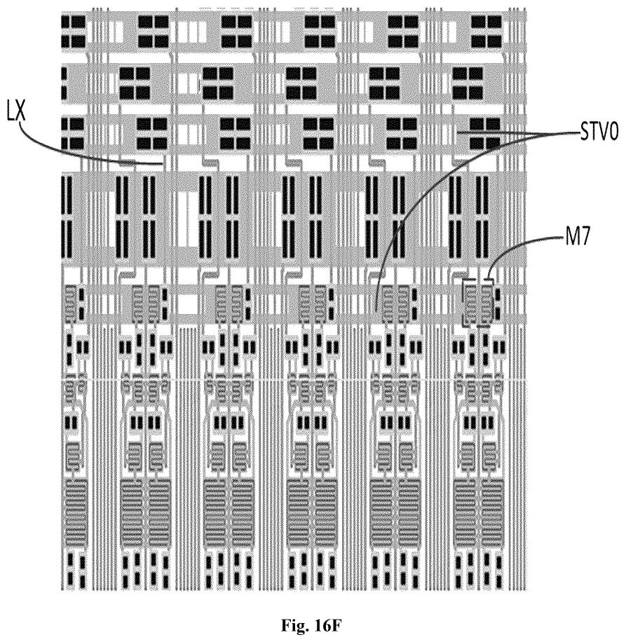

FIG. 16A is a schematic diagram of the marking of each transistor and capacitor in the driving circuit added on the basis of FIG. 14.

In at least one embodiment shown in FIG. 16A, the second one of the first low-voltage line VGL21 is arranged at the side of the fourth transistor M4 close to the display region.

FIG. 16B is a partial enlarged view of the first part of the driving circuit in an order from top to bottom;

FIG. 16C is a partial enlarged view of the second part of the driving circuit in an order from top to bottom;

FIG. 16D is a partial enlarged view of the third part of the driving circuit in an order from top to bottom;

FIG. 16E is a partial enlarged view of the fourth part of the driving circuit in an order from top to bottom.

FIG. 16F is a partial enlarged view of FIG. 16A.

As shown in FIG. 16F, the signal line electrically connected to the gate electrode of the seventh transistor M7 and the signal line located above the M7 are both frame reset lines STV0;

the frame reset line STV0 can be formed in the gate metal layer;

the signal line electrically connected to the gate electrode of the seventh transistor M7 and the signal line located above the M7 may be electrically connected to the connection line LX arranged on the source-drain metal layer, and the quantity of the connection lines LX may be multiple.

In at least one embodiment of the present disclosure, the first gate line and the second data line intersect to define a sub-pixel region, and the sub-pixel region includes a sub-electrode;

a length of the sub-electrode included in the sub-pixel region farthest from the driver module along the second direction is less than a first length;

the first length is a shortest length of a sub-electrode included in another sub-pixel region along the second direction, the other sub-pixel region is other than the sub-pixel region farthest from the driver module.

In a specific implementation, in the display region, the first gate line and the second data line intersect to define a sub-pixel region, and the sub-pixel driving may include a pixel electrode and a common electrode, the common electrode is an integral electrode, and the pixel electrode is separate, and the length of the sub-electrode included in the sub-pixel region farthest from the driver module along the vertical direction is less than the length of another pixel circuit along the vertical direction. The space saved may be used for other designs, for example, an Array Test (AT) component may be arranged to achieve normal AT detection while realizing an ultra-narrow bezel; currently, this design may also be applied to a bezel-less screen and can be mass-produced.

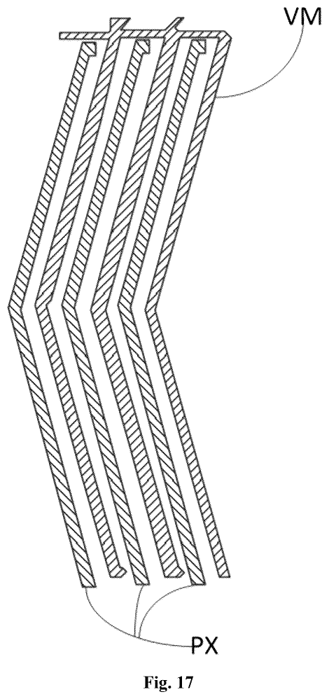

In at least one embodiment of the present disclosure, the sub-electrode may include a common electrode and a pixel electrode, and the common electrode and the pixel electrode are both dual-domain structures, and the dual-domain structure includes an upper domain structure and a lower domain structure electrically connected to each other, and an extension direction of the upper domain structure is different from an extension direction of the lower domain structure. The reduction in the length of the sub-electrode included in the sub-pixel region farthest from the driver module along the second direction may be achieved in the following three ways: reducing the length of the upper domain structure along the second direction, reducing the length of the lower domain structure along the second direction, or reducing the length of the upper domain structure along the second direction and the length of the lower domain structure along the second direction. Referring to FIG. 17, in this case, for the pixel in the display region, optionally, the pixel electrode and the common electrode are arranged in a same layer, and are arranged alternately in a comb-like manner, and the pixel electrode includes a plurality of branch electrode portions, and an end of the branch electrode includes a widened portion, and the design of the widened portion may improve the problem of dimming in an edge region of the pixel.

In the related art, at a Data Pad Opposite (DPO) side, due to the tight border and insufficient design space for other processes, a black matrix may be used to cover part of a light-emitting region of the sub-pixel region farthest from the driver module. The covered portion will not display an image. In at least one embodiment of the present disclosure, it directly removes part of the light-emitting region, which is equivalent to the height of a row of pixels farthest from the driver module being ⅔ of the height of normal pixels, so that the saved space may be used for other designs.

As shown in FIG. 17, the length of the common electrode VM along the vertical direction and the length of the pixel electrode PX along the vertical direction included in the sub-pixel region close to the driver module are larger.

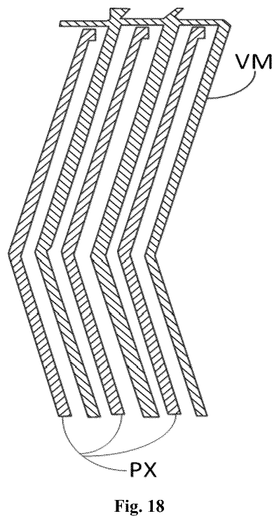

As shown in FIG. 18, the length of the common electrode VM along the vertical direction and the length of the pixel electrode PX along the vertical direction included in the sub-pixel region farthest from the driver module are smaller.

In at least one embodiment shown in FIG. 18, the length of the lower domain structure included in the common electrode along the vertical direction is reduced, and the length of the lower domain structure included in the pixel electrode in the vertical direction is reduced, so as to save space.

In at least one embodiment of the present disclosure, the common electrode and the pixel circuit may both be formed in an Indium Tin Oxide (ITO) layer, but the present disclosure is not limited thereto.

Optionally, the array substrate includes a display region and a peripheral region;

the peripheral region includes a first virtual pattern region arranged at a first side of the display region and/or a second virtual pattern region arranged at a fourth side of the display region; the first side and the fourth side are opposite sides;

the array substrate includes a first virtual pattern array arranged in the first virtual pattern region, and/or a second virtual pattern array arranged in the second virtual pattern region;

the first virtual pattern array includes a plurality of first virtual patterns arranged in an array, and the second virtual pattern array includes a plurality of second virtual patterns arranged in an array; the first virtual pattern is configured to support sealant, and the second virtual pattern is configured to support the sealant.

In at least one embodiment of the present disclosure, the first side may be the left side, and the second side may be the right side, but the present disclosure is not limited thereto

In the related art, when designing a narrow-bezel display product, it will also consider to reduce the cost, so it will be necessary to be compatible with a large bezel design requirement. Therefore, if there is a blank region design between the large-bezel panel edge and the small-bezel panel edge, certain problems will occur in a subsequent cell process, resulting in the display product being unable to be produced normally, so it is necessary to add a virtual pattern design. Problems that may arise in the cell process may be, for example: when manufacturing a large-bezel display panel, a sealant will be coated on the increased bezel region. When the virtual pattern is not added, the height of the peripheral sealant will be problematic, resulting in a peripheral yellowing defect. Based on this, in at least one embodiment of the present disclosure, a virtual pattern region is arranged at the first side and/or the second side of the display region, with a virtual pattern array arranged within the virtual pattern region. The virtual pattern array includes a plurality of virtual patterns arranged in an array to support the sealant, thereby reducing the peripheral yellowing defect phenomenon.

Optionally, the first virtual pattern may be formed in the gate metal layer or the source-drain metal layer, and the second virtual pattern may be formed in the gate metal layer or the source-drain metal layer.

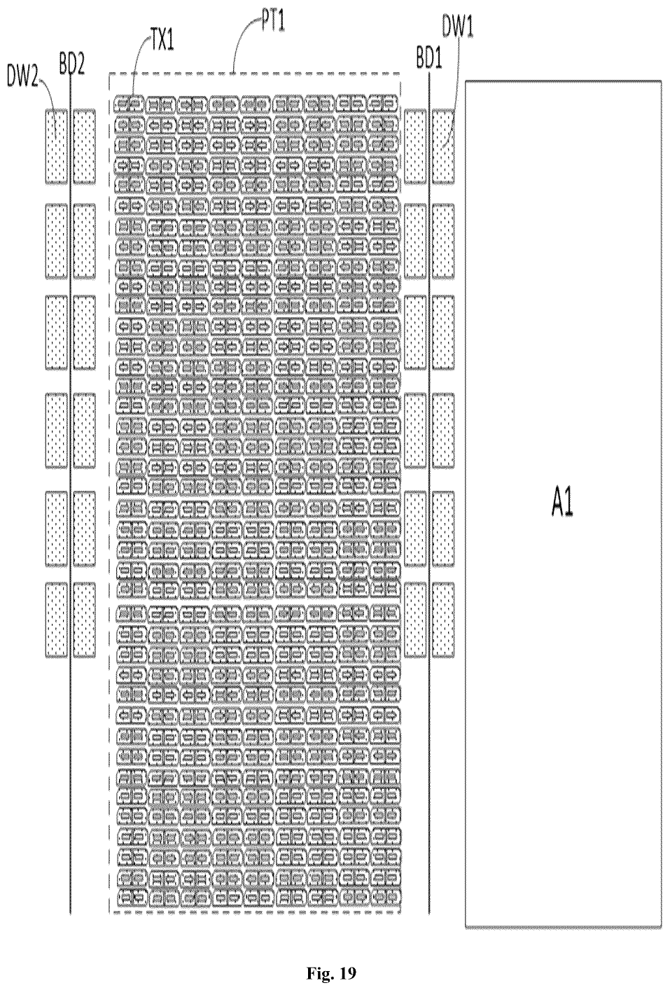

As shown in FIG. 19, a reference sign A1 denotes a display region;

a reference sign BD1 denotes a first boundary, and a reference sign BD2 denotes a second boundary;

the display region A1 is arranged at the side of the first boundary BD1 distal to the second boundary BD2;

the first virtual pattern region PT1 is arranged at the left side of the display region A1, and the array substrate includes a first virtual pattern array arranged in the first virtual pattern region PT1;

the first virtual pattern array includes a plurality of first virtual patterns TX1 arranged in an array;

the first virtual pattern TX1 is configured to support the sealant.

In at least one embodiment shown in FIG. 19, the first virtual pattern array may be formed in the gate metal layer, and the first virtual pattern TX1 is a rectangular virtual pattern.

In FIG. 19, a reference sign DW1 denotes a first alignment mark, and a reference sign DW2 denotes a second alignment mark. The first alignment mark DW1 and the second alignment mark DW2 may both be formed in the gate metal layer, and DW1 and DW2 may be used for an alignment cutting line.

When a narrow bezel display panel needs to be made, cutting is performed from the first boundary BD1, and when a large bezel display panel needs to be made, cutting is performed from the second boundary BD2.

Optionally, the first virtual pattern may also be a Chinese character “ [symbol] ” shaped virtual pattern or a Chinese character “ [symbol] ” shaped virtual pattern, but the present disclosure is not limited thereto.

In at least one embodiment of the present disclosure, the array substrate includes the peripheral region; the peripheral region includes a binding region; the array substrate includes a binding pad arranged in the binding region;

the binding pad is electrically connected to the first data line, and the binding pad is electrically connected to a conductive connection pattern through a via hole, and an edge of the via hole is serrated.

In a specific implementation, the peripheral region includes a binding region, the array substrate includes a binding pad, the binding pad is arranged in the binding region, and a pad of a flexible circuit board is electrically connected to the binding pad through the conductive connection pattern, and the conductive connection pattern may be formed in the ITO layer, but the present disclosure is not limited thereto.

Optionally, the binding pad may be formed in the gate metal layer, the binding pad is electrically connected to the conductive connection pattern, and the conductive connection pattern may be electrically connected to the pad of the flexible circuit board through a via hole penetrating through an organic film layer. However, due to the relatively thick organic film layer, a tool needs to be used for pressing in the bonding region, which poses a risk of cracking at the edge of the via hole. Therefore, in at least one embodiment of the present disclosure, the edge of the via hole is designed in a serrated shape to share the pressure caused by sudden change at the edge of the via hole, preventing the edge of the via hole from cracking. The via hole may be used for a bezel-less display product.

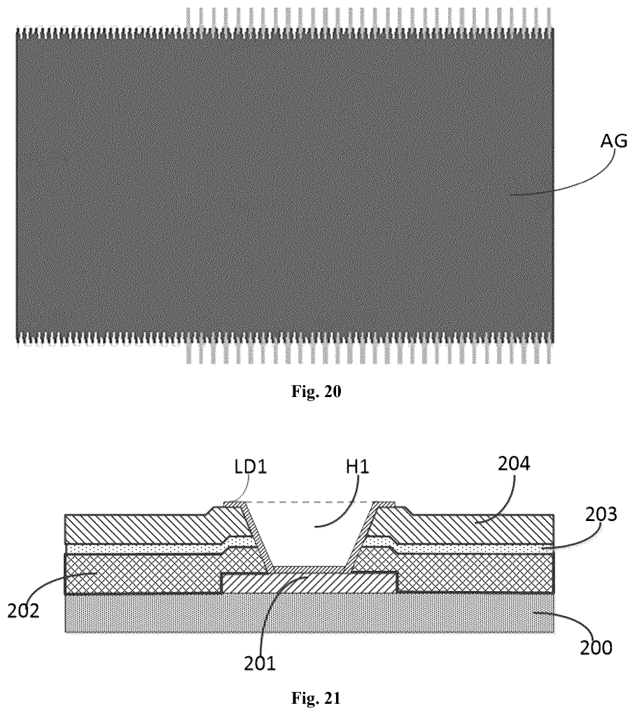

FIG. 20 is a top view of a via hole region AG occupied by a via hole penetrating through an organic film layer. As shown in FIG. 20, the edge of the via hole region AG is serrated.

In FIG. 21, a reference sign H1 denotes a via hole, a reference sign 200 denotes a base substrate, a reference sign 201 denotes a gate metal layer, a reference sign 202 denotes a gate insulating layer, a reference sign 203 denotes a passivation layer, a reference sign 204 denotes an organic film layer, and a reference sign L1 denotes a conductive connection pattern;

the via hole H1 is a via hole that penetrates through the passivation layer 202, the gate insulating layer 203 and the organic film layer 204, the binding pad and the first data line are formed on the gate metal layer 201, and the conductive connection pattern LD1 is formed on the ITO layer. When manufacturing the display panel, the conductive connection pattern LD1 is electrically connected to a source driver through the via hole H1.

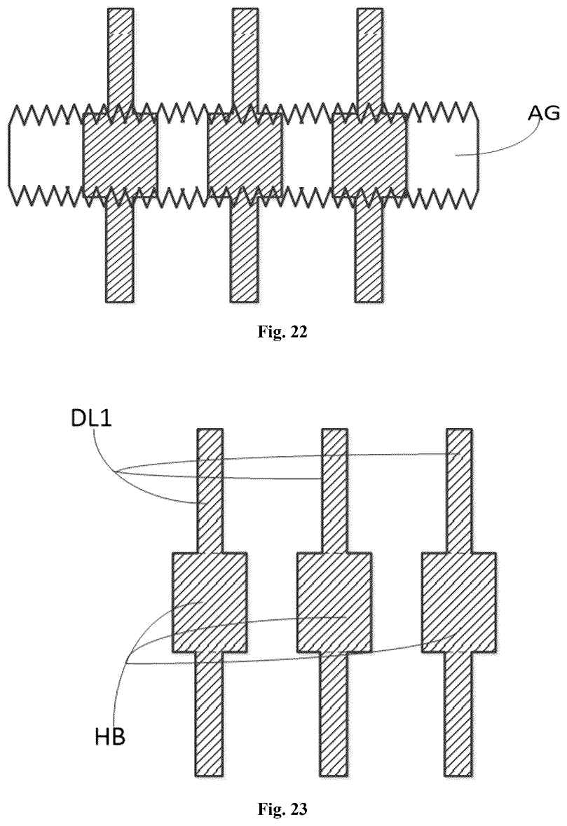

In FIG. 22, a reference sign AG denotes a via hole region, and the edge of the via hole region AG is serrated.

FIG. 23 is a layout diagram of the gate metal layer in FIG. 22. As shown in FIG. 23, a reference sign HB denotes a binding pad, and a reference sign DL1 denotes a first data line.

In the embodiments of the present disclosure, a display device includes the above-mentioned array substrate.

The above are preferred embodiments of the present disclosure. It should be noted that for those of ordinary skill in the art, certain improvements and modifications can be made without departing from the principles disclosed in the present disclosure, and these improvements and modifications should also be considered to be within the scope of the present disclosure.

1. An array substrate, comprising a base substrate, a first data line, a virtual signal line and a driver module, wherein the first data line, the virtual signal line and the driver module are arranged on the base substrate, wherein the first data line, the virtual signal line and the driver module are arranged in a peripheral region of the array substrate, the peripheral region at least partially surrounds a display region, the display region comprises a first gate line extending along a first direction and a second data line extending along a second direction, the first data line is electrically connected to the second data line, and the first direction intersects the second direction;
the driver module is arranged at a first side of the array substrate; the first side is a side arranged in an extension direction of the second data line;
the driver module comprises multiple stages of driving circuits; the multiple stages of driving circuits are arranged along the first direction; the driving circuit is configured to provide a driving signal;
the first data line is arranged between at least two adjacent driving circuits, and the first data line is configured to provide a data voltage;
the virtual signal line is further arranged between the at least two adjacent driving circuits; the virtual signal line is in a floating state.

2. The array substrate according to claim 1, wherein the first data line and the virtual signal line are formed in a same conductive layer.

3. The array substrate according to claim 2, wherein at least one of the virtual signal lines is arranged between two adjacent first data lines;
the virtual signal line extends along the second direction.

4. The array substrate according to claim 1, wherein the peripheral region comprises a driving circuit region and a side region; the driver module is arranged in the driving circuit region;
the side region is arranged at two opposite sides of an arrangement direction of the driving circuit region;
the side region comprises a first signal line region and a first electrostatic discharge region; the array substrate further comprises a plurality of clock signal lines arranged in the first signal line region, and a first electrostatic discharge circuit arranged in the first electrostatic discharge region;
the first electrostatic discharge circuit is electrically connected to the clock signal line, and configured to provide electrostatic protection for the clock signal line.

5. The array substrate according to claim 4, wherein the array substrate further comprises a first one of first low voltage lines, a second low voltage line, a frame reset line, a first control voltage line, a second control voltage line and an initial voltage line that are arranged in the first signal line region;
the first electrostatic discharge circuit is further electrically connected to each of the first one of the first low voltage lines, the second low voltage line, the frame reset line, the first control voltage line, the second control voltage line and the initial voltage line, and is configured to provide electrostatic protection for the first one of the first low voltage lines, the second low voltage line, the frame reset line, the first control voltage line, the second control voltage line and the initial voltage line;
the first one of the first low voltage lines is configured to provide a first low voltage signal, the frame reset line is configured to provide a frame reset signal, the first control voltage line is configured to provide a first control voltage, the second control voltage line is configured to provide a second control voltage, and the initial voltage line is configured to provide an initial voltage.

6. The array substrate according to claim 5, wherein the clock signal line, the second low voltage line, the frame reset line, the first control voltage line and the second control voltage line are arranged at a first side, a second side and a third side of the first electrostatic discharge circuit; the first one of the first low voltage lines is arranged at the first side and the second side of the first electrostatic discharge circuit; the initial voltage line is arranged at a fourth side of the first electrostatic discharge circuit;
the first side and the fourth side are opposite sides, and the second side and the third side are opposite sides.

7. The array substrate according to claim 1, wherein the array substrate comprises a driving circuit region and a display region, the driver module is arranged in the driving circuit region; the driving circuit region comprises a wiring region;
the array substrate further comprises a second one of first low voltage lines arranged between the driving circuit region and the display region, and a cascade line arranged in the wiring region;
the cascade line is a signal line for cascading the multiple stages of driving circuits comprised in the driver module; the second one of the first low voltage lines is configured to provide a first low voltage signal;
an orthographic projection of the virtual signal line onto the base substrate overlaps at least partially with an orthographic projection of the cascade line onto the base substrate;
the orthographic projection of the virtual signal line onto the base substrate overlaps at least partially with an orthographic projection of the second one of the first low voltage lines onto the base substrate.

8. The array substrate according to claim 4, wherein the peripheral region comprises a virtual driving circuit region; the array substrate comprises a virtual driver module arranged in the virtual driving circuit region, and the virtual driving circuit region is arranged between the side region and the display region;
the virtual driver module comprises a plurality of virtual driving circuits arranged along the first direction;
the virtual driving circuit comprises a virtual driving output end and a virtual input end;
the virtual input end of the virtual driving circuit is disconnected from a virtual driving output end of another virtual driving circuit comprised in the virtual driver module other than the virtual driving circuit.

9. The array substrate according to claim 8, wherein the array substrate further comprises a floating signal line arranged between adjacent virtual driving circuits;
the floating signal line is in a floating state.

10. The array substrate according to claim 1, wherein the array substrate comprises the peripheral region and the display region, the peripheral region comprises a driving circuit region; the driver module is arranged in the driving circuit region;
the peripheral region further comprises a common electrode wiring region arranged at a side of the driving circuit region distal to the display region, and a second signal line region arranged between the common electrode wiring region and the driving circuit region;
the array substrate further comprises a common electrode wiring, a common electrode connection line and a common electrode arranged in the display region; the common electrode wiring is electrically connected to the common electrode through the common electrode connection line;
the common electrode wiring is located in the common electrode wiring region;
the common electrode connection line traverses the second signal line region and the driving circuit region.

11. The array substrate according to claim 10, wherein the array substrate further comprises a plurality of clock signal lines, a first control voltage line, a second control voltage line, a frame reset line and a second low voltage line that are arranged in the second signal line region.

12. The array substrate according to claim 10, wherein the array substrate comprises the peripheral region and the display region, the peripheral region comprises the driving circuit region; the driver module is arranged in the driving circuit region;
the peripheral region further comprises the second signal line region arranged at the side of the driving circuit region distal to the display region;
the array substrate further comprises a plurality of clock signal lines arranged in the second signal line region; the clock signal line extends along the first direction, and the plurality of clock signal lines are arranged along the second direction;
the clock signal connection line electrically connected to the clock signal line at a side proximate to the display region comprises a winding portion relative to the clock signal connection line electrically connected to the clock signal line proximate to the common electrode wiring region.

13. The array substrate according to claim 1, wherein the first gate line and the second data line intersect to define a sub-pixel region, and the sub-pixel region comprises a sub-electrode;
a length of the sub-electrode comprised in the sub-pixel region farthest from the driver module along the second direction is less than a first length;
the first length is a shortest length of a sub-electrode comprised in another sub-pixel region along the second direction, the other sub-pixel region is other than the sub-pixel region farthest from the driver module.

14. The array substrate according to claim 1, wherein the array substrate comprises a display region and a peripheral region;
the peripheral region comprises a first virtual pattern region arranged at a first side of the display region and/or a second virtual pattern region arranged at a fourth side of the display region; the first side and the fourth side are opposite sides;
the array substrate comprises a first virtual pattern array arranged in the first virtual pattern region, and/or a second virtual pattern array arranged in the second virtual pattern region;
the first virtual pattern array comprises a plurality of first virtual patterns arranged in an array, and the second virtual pattern array comprises a plurality of second virtual patterns arranged in an array; the first virtual pattern is configured to support sealant, and the second virtual pattern is configured to support the sealant.

15. The array substrate according to claim 14, wherein the array substrate comprises the peripheral region; the peripheral region comprises a binding region; the array substrate comprises a binding pad arranged in the binding region;
the binding pad is electrically connected to the first data line, and the binding pad is electrically connected to a conductive connection pattern through a via hole, and an edge of the via hole is serrated.

16. The array substrate according to claim 1, wherein the array substrate further comprises a second gate line extending along the second direction;
the first gate line is electrically connected to the second gate line, and the second gate line is electrically connected to the driver module.

17. The array substrate according to claim 1, wherein the first gate line and the second data line intersect to define a sub-pixel region;
a quantity of the first data lines between adjacent driving circuits is greater than or equal to m/(n+2) and less than or equal to m/(n−1);
n is a quantity of the first gate lines, m is a quantity of the second data lines corresponding to the sub-pixel region, and m and n are positives.

18. The array substrate according to claim 1, wherein a quantity of the virtual signal lines is less than a quantity of the first data lines.

19. A display device, comprising the array substrate according to claim 1.

20. The display device according to claim 19, wherein the first data line and the virtual signal line are formed in a same conductive layer.
